(19) United States
(12) Patent Application Publication
(10) Pub. No.: US 2024/0240079 A1
(43) Pub. Date: Jul. 18, 2024

(54) SEMICONDUCTOR NANOPARTICLES AND METHOD OF PRODUCING THEREOF

(71) Applicant: NICHIA CORPORATION, Anan-shi (JP)

(72) Inventors: Yohei IKAGAWA, Naruto-shi (JP); Shun KATO, Anan-shi (JP)

(73) Assignee: NICHIA CORPORATION, Anan-shi (JP)

(21) Appl. No.: 18/532,461

(22) Filed: Dec. 7, 2023

(30) Foreign Application Priority Data
Dec. 9, 2022 (JP) 2022-197388
Jul. 6, 2023 (JP) 2023-111396

(51) Int. Cl. C09K 11/62; B82Y 20/00; B82Y 40/00

(52) U.S. Cl. CPC C09K 11/621; B82Y 20/00; B82Y 40/00

(57) ABSTRACT

A method of producing semiconductor nanoparticles includes: providing first semiconductor nanoparticles containing a first semiconductor containing Ag, In, Ga, and S, and a second semiconductor disposed on a surface of the first semiconductor and containing Ga and S; performing a first heat treatment of a first mixture containing the first semiconductor nanoparticles, a Ga source, and an S source to obtain a first heat-treated product comprising semiconductor composite particles; and performing a second heat treatment of a second mixture containing the semiconductor composite particles and a gallium halide to obtain a second heat-treated product.

### CROSS-REFERENCE TO RELATED APPLICATIONS

This application claims priority to Japanese Patent Application No. 2022-197388, filed on Dec. 9, 2022, and Japanese Patent Application No. 2023-111396, filed on Jul. 6, 2023, the disclosures of which are hereby incorporated by reference in their entirety.

### TECHNICAL FIELD

The present disclosure relates to semiconductor nanoparticles and a method of producing semiconductor nanoparticles.

### BACKGROUND

Semiconductor particles having a particle size of, for example, 20 nm or smaller are known to exhibit a quantum size effect, and such nanoparticles are referred to as “quantum dots” (also referred to as “semiconductor quantum dots”). The “quantum size effect” refers to a phenomenon in which a valence band and a conduction band that are each regarded as continuous in bulk particles become discrete when the particle size is on the nanoscale and the band-gap energy varies with the particle size.

Quantum dots are capable of absorbing light and converting the wavelength into a light corresponding to their band-gap energy; therefore, white light emitting devices utilizing emission of such quantum dots have been proposed. In this connection, an efficient method for producing ternary semiconductor nanoparticles capable of band edge emission and having a low toxicity composition has been proposed (see, for example, WO 2022/191032).

In semiconductor nanoparticles capable of band edge emission, further improvement of durability is expected. An aspect of the present disclosure is to provide semiconductor nanoparticles with excellent durability and a method for producing the same.

### SUMMARY

A first embodiment is a method of producing semiconductor nanoparticles, the method including:
providing first semiconductor nanoparticles containing a first semiconductor containing silver (Ag), indium (In), gallium (Ga), and sulfur (S), and a second semiconductor disposed on a surface of the first semiconductor and containing gallium (Ga) and sulfur (S);
performing a first heat treatment of a first mixture containing the first semiconductor nanoparticles, a gallium (Ga) source, and a sulfur (S) source to obtain a first heat-treated product comprising semiconductor composite particles; and
performing a second heat treatment of a second mixture comprising the semiconductor composite particles and a gallium halide to obtain a second heat-treated product.

A second embodiment is semiconductor nanoparticles that contain:
a semiconductor containing silver (Ag), indium (In), gallium (Ga), and sulfur (S); and
an additional semiconductor disposed on a surface of the semiconductor and containing Ga and S. The semiconductor nanoparticles may have an average particle size that is 7.5 nm or larger, an internal quantum yield that is 50% or higher, and a full width at half maximum that is 30 nm or smaller in an emission spectrum.

According to an aspect of the present disclosure, it is possible to provide semiconductor nanoparticles with excellent durability and a method for producing the same.

### BRIEF DESCRIPTION OF DRAWINGS

FIG. 1 shows an exemplary emission spectrum of the semiconductor nanoparticles according to Example 1 before and after the purification step.

FIG. 2 shows an exemplary emission spectrum of the semiconductor nanoparticles according to Comparative Example before and after the purification step.

FIG. 3 shows an exemplary emission spectrum of the semiconductor nanoparticles according to Example 2 before and after the purification step.

FIG. 4 shows an exemplary emission spectrum of the semiconductor nanoparticles according to Example 3 before and after the purification step.

FIG. 5 shows an exemplary emission spectrum of the semiconductor nanoparticles according to Example 4 before and after the purification step.

FIG. 6 shows a relationship between the average particle size of semiconductor nanoparticles according to the Examples and the full width at half maximum in the respective emission spectrum.

### DETAILED DESCRIPTION

The term “step” used herein encompasses not only a discrete step but also a step that cannot be clearly distinguished from other steps, as long as the intended purpose of the step is achieved. When there are plural substances that correspond to a component of a composition, an indicated amount of the component contained in the composition means, unless otherwise specified, a total amount of the plural substances existing in the composition. Further, as an upper limit and a lower limit of a numerical range described in the present specification, the values exemplified for the numerical range can be arbitrarily selected and combined. In the present specification, in the formula representing the composition of the quantum dot, phosphor or light-emitting material, the plurality of elements listed separated by commas (,) means at least one of these elements is contained in the composition. In the formula representing the composition of the phosphor, the part preceding a colon (:) represents a host crystal, and the part following the colon (:) represents an activation element. The relationship between the color name and chromaticity coordinates, the relationship between the wavelength range of light and the color name of monochromatic light, etc. conform to JIS Z8110. In an emission spectrum of a phosphor, the half-width of the phosphor means the wavelength width of the emission spectrum at which the emission intensity is 50% relative to the maximum emission intensity (full width at half maximum; FWHM). Embodiments of the present disclosure will now be described in detail. However, the below-described embodiments are merely examples of a method of producing semiconductor nanoparticles that embody the technical idea of the present disclosure, and the present invention is not limited to the below-described method of producing semiconductor nanoparticles.

### Method of Producing Semiconductor Nanoparticles

The method of producing semiconductor nanoparticles includes: the first step of providing first semiconductor nanoparticles that contain a first semiconductor containing silver (Ag), indium (In), gallium (Ga), and sulfur (S), and a second semiconductor disposed on a surface of the first semiconductor and containing gallium (Ga) and sulfur (S); the second step of performing a first heat treatment of a first mixture, that contains the thus provided first semiconductor nanoparticles, a gallium (Ga) source, and a sulfur (S) source, to obtain a first heat-treated product containing semiconductor composite particles; and the third step of performing a second heat treatment of a second mixture that contains the semiconductor composite particles obtained in the second step and a gallium halide, to obtain a second heat-treated product containing desired semiconductor nanoparticles (hereinafter, also referred to as “second semiconductor nanoparticles”).

Semiconductor nanoparticles having good durability may be produced by supplying a Ga source and a S source to the first semiconductor nanoparticles having a structure in which the second semiconductor is disposed on the surface of the first semiconductor so as to dispose a compound containing Ga and S on the surfaces of the first semiconductor nanoparticles and obtain semiconductor composite particles, and subsequently treating the surfaces of the thus obtained semiconductor composite particles with a gallium halide. This is believed to be because, for example, a semiconductor formed on the surfaces of the first semiconductor nanoparticles may protect the first semiconductor nanoparticles from the effects of the external environment. The term “good durability” used herein means that, for example, even when the semiconductor nanoparticles are washed with an organic solvent or the like in the production process of the semiconductor nanoparticles, a reduction in the internal quantum yield of the emission of the semiconductor nanoparticles is reduced or suppressed. The semiconductor nanoparticles obtained by the above-described method of producing semiconductor nanoparticles may exhibit band-edge emission and have a high internal quantum yield.

In the first step, the first semiconductor nanoparticles, which contain a first semiconductor containing Ag, In, Ga, and S, and a second semiconductor disposed on a surface of the first semiconductor and containing Ga and S, are provided. The first semiconductor nanoparticles may be provided by acquisition of the desired first semiconductor nanoparticles, or by producing the desired first semiconductor nanoparticles in accordance with the below-described production method. The details of the first semiconductor nanoparticles will be described below.

In the second step, a first heat-treated product containing semiconductor composite particles is obtained by performing a first heat treatment of a first mixture that contains the above-provided first semiconductor nanoparticles, a gallium (Ga) source, and a sulfur (S) source. In the semiconductor composite particles contained in the first heat-treated product, a compound containing Ga and S may be disposed on the surfaces of the first semiconductor nanoparticles. The compound containing Ga and S, which is disposed on the surfaces of the first semiconductor nanoparticles, may be a semiconductor compound and may contain gallium sulfide, or may be a compound composed of substantially Ga and S. The compound containing Ga and S may have a stoichiometric composition (e.g., Ga₂S₃), or may have a composition different from a stoichiometric composition.

The Ga source contained in the first mixture is, for example, a Ga salt. The Ga salt may be either an organic acid salt or an inorganic acid salt. Specifically, examples of the inorganic acid salt include halides, nitrates, sulfates, and hydrochlorides, and examples of the organic acid salt include formates, acetates, oxalates, acetylacetonates, and sulfonates. The Ga salt may preferably contain at least one selected from the group consisting of these acid salts, and the Ga salt may more preferably contain at least one selected from the group consisting of organic acid salts such as acetates and acetylacetonates because these salts are highly soluble in organic solvents and thus allow reaction to proceed more uniformly. In the first mixture, the Ga salt may be contained singly, or in combination of two or more thereof.

The Ga source in the first mixture may contain a compound having a Ga—S bond. The Ga—S bond may be any of a covalent bond, an ionic bond, a coordinate bond, and the like. Examples of the compound having a Ga—S bond include Ga salts of sulfur-containing compounds, and the compound having a Ga—S bond may be an organic acid salt, inorganic acid salt, organic metal compound, or the like of Ga. Examples of the sulfur-containing compounds specifically include thiocarbamic acids, dithiocarbamic acids, thiocarbonic acid esters, dithiocarbonic acid esters (xanthic acid), trithiocarbonic acid esters, thiocarboxylic acids, dithiocarboxylic acids, and derivatives thereof. Thereamong, at least one selected from the group consisting of xanthic acid and derivatives thereof is preferred because these compounds are decomposed at a relatively low temperature. Specific examples of the sulfur-containing compounds include aliphatic thiocarbamic acids, aliphatic dithiocarbamic acids, aliphatic thiocarbonic acid esters, aliphatic dithiocarbonic acid esters, aliphatic trithiocarbonic acid esters, aliphatic thiocarboxylic acids, and aliphatic dithiocarboxylic acids. Examples of the aliphatic groups in these sulfur-containing compounds include alkyl groups and alkenyl groups that have 1 to 12 carbon atoms. The aliphatic thiocarbamic acids may include dialkylthiocarbamic acids and the like, and the aliphatic dithiocarbamic acids may include dialkyldithiocarbamic acids and the like. The alkyl groups in the dialkylthiocarbamic acids and the dialkyldithiocarbamic acids may have, for example, 1 to 12 carbon atoms, preferably 1 to 4 carbon atoms. Two alkyl groups in the dialkylthiocarbamic acids and the dialkyldithiocarbamic acids may be the same or different. Specific examples of the compound having a Ga—S bond include gallium tris(dimethyldithiocarbamate), gallium tris(diethyldithiocarbamate) (Ga(DDTC)₃), gallium chloro-bis(diethyldithiocarbamate), and gallium ethyl xanthate (Ga(EX)₃). In the first mixture, the compound having a Ga—S bond may be contained singly, or in combination of two or more thereof.

Examples of the S source in the first mixture include simple substance of sulfur and sulfur-containing compounds. As the S source, for example, simple substance of sulfur such as high-purity sulfur, or a sulfur-containing compound, examples of which include: thiols such as n-butanethiol, isobutanethiol, n-pentanethiol, n-hexanethiol, octanethiol, decanethiol, dodecanethiol, hexadecanethiol, and octadecanethiol; disulfides such as dibenzyl sulfide; thiourea; thiocarbonyl compounds; and thiocarbamic acids, dithiocarbamic acids, thiocarbonic acid esters, dithiocarbonic acid esters (xanthic acid), trithiocarbonic acid esters, thiocarboxylic acids, dithiocarboxylic acids, and derivatives of these compounds, can be used. The S source in the first mixture may double as the Ga source. For example, a compound having a Ga—S bond can be used as both the Ga source and the S source in the first mixture.

The content of the Ga source and the content of the S source in the first mixture may be selected such that a desired amount of a compound containing Ga and S is disposed on the surfaces of the first semiconductor nanoparticles, taking into consideration the amount of the first semiconductor nanoparticles contained in the first mixture. For example, the addition amounts of the Ga source and the S source may be determined such that a compound having a stoichiometric composition composed of Ga and S is generated in an amount of 0.01 mmol to 10 mmol, particularly 0.1 mmol to 1 mmol, with respect to 10 nmol of the first semiconductor nanoparticles in terms of the amount of substance as particles. It is noted here that the “amount of substance as particles” refers to a molar amount assuming a single first semiconductor nanoparticle as a huge molecule, and is equal to a value obtained by dividing the number of the first semiconductor nanoparticles contained in the first mixture by Avogadro constant (NA=6.022×10²³).

The content of the Ga source in the first mixture may be any amount at which, for example, the ratio of the number of moles of Ga contained in the Ga source with respect to the number of moles of the first semiconductor nanoparticles is 5.0×10³ or higher and 6.0×10⁴ or lower, preferably 6.7×10³ or higher, 1.5×10⁴ or higher, or 2.0×10⁴ or higher, but preferably 4.5×10⁴ or lower, 4.0×10⁴ or lower, or 3.0×10⁴ or lower.

The first mixture may further contain a silver (Ag) source in addition to the Ga source and the S source. The Ag source is, for example, an Ag salt. The Ag salt may be either an organic acid salt or an inorganic acid salt. Specifically, examples of the inorganic acid salt include halides, nitrates, sulfates, and hydrochlorides, and examples of the organic acid salt include formates, acetates, oxalates, acetylacetonates, and sulfonates. The Ag salt may preferably contain at least one selected from the group consisting of these acid salts, and the Ag salt may more preferably contain at least one selected from the group consisting of organic acid salts such as acetates and acetylacetonates because these salts are highly soluble in organic solvents and thus allow reaction to proceed more uniformly. In the first mixture, the Ag salt may be contained singly, or in combination of two or more thereof.

The Ag salt in the first mixture may contain a compound having a Ag—S bond. The Ag—S bond may be any of a covalent bond, an ionic bond, a coordinate bond, and the like. Examples of the compound having an Ag—S bond include Ag salts of sulfur-containing compounds, and the compound having a Ag—S bond may be an organic acid salt, inorganic acid salt, organic metal compound, or the like of Ag. Examples of the sulfur-containing compounds include thiocarbamic acids, dithiocarbamic acids, thiocarbonic acid esters, dithiocarbonic acid esters (xanthic acid), trithiocarbonic acid esters, thiocarboxylic acids, dithiocarboxylic acids, and derivatives thereof. Thereamong, at least one selected from the group consisting of xanthic acid and derivatives thereof is preferred because these compounds are decomposed at a relatively low temperature. Specific examples of the sulfur-containing compounds are the same as or similar to those exemplified above for the compound having a Ga—S bond. Specific examples of the compound having a Ag—S bond include silver dimethyldithiocarbamate, silver diethyldithiocarbamate (Ag(DDTC)), and silver ethyl xanthate (Ag(EX)).

The content of the Ag source in the first mixture may be any amount at which, for example, the ratio of the number of moles of Ag contained in the Ag source with respect to the number of moles of the first semiconductor nanoparticles is 1.0×10³ or higher and 1.0×10⁴ or lower, preferably 2×10³ or higher, but preferably 7×10³ or lower, or 5×10³ or lower. When the first mixture contains the Ag source, the ratio of the number of moles of Ga contained in the Ga source with respect to the number of moles of the first semiconductor nanoparticles may be 5.0×10³ or higher and 8.0×10⁴ or lower, preferably 1.0×10⁴ or higher, or 2.0×10⁴ or higher, but preferably 7.0×10⁴ or lower, 6.0×10⁴ or lower, or 3.0×10⁴ or lower. Further, the ratio of the number of moles of Ag contained in the Ag source with respect to the number of moles of gallium contained in the Ga source contained in the first mixture may be, for example, 0.04 to 0.33, preferably 0.08 or higher, 0.12 or higher, or 0.14 or higher, but preferably 0.24 or lower, 0.2 or lower, or 0.17 or lower.

The first mixture may contain an organic solvent. Examples of the organic solvent in the first mixture include: amines containing a hydrocarbon group having 4 to 20 carbon atoms, such as alkylamines and alkenylamines having 4 to 20 carbon atoms; thiols containing a hydrocarbon group having 4 to 20 carbon atoms, such as alkylthiols and alkenylthiols having 4 to 20 carbon atoms; and phosphines containing a hydrocarbon group having 4 to 20 carbon atoms, such as alkylphosphines and alkenylphosphines having 4 to 20 carbon atoms, and the first mixture preferably contains at least one selected from the group consisting of these organic solvents. These organic solvents may, for example, eventually modify the surfaces of the resulting first semiconductor nanoparticles. These organic solvents may be used in combination of two or more thereof and, for example, a mixed solvent of a combination of at least one selected from thiols containing a hydrocarbon group having 4 to 20 carbon atoms and at least one selected from amines containing a hydrocarbon group having 4 to 20 carbon atoms may be used. These organic solvents may also be used as a mixture with other organic solvent. When the organic solvent contains any of the above-described thiols and any of the above-described amines, a content volume ratio of the thiol with respect to the amine (thiol/amine) may be, for example, higher than 0 and 1 or lower, preferably 0.007 or higher and 0.2 or lower.

The concentration of the first semiconductor nanoparticles in the first mixture may be, for example, 5.0×10⁻⁸ mol/L or higher and 5.0×10⁻⁶ mol/L or lower, preferably 1.0×10⁻⁷ mol/L or higher, or 3.0×10⁻⁷ mol/L or higher, or preferably 2.5×10⁶ mol/L or lower, 1.0×10⁻⁶ mol/L or lower, or 6.0×10⁻⁷ mol/L or lower,

In the second step, a first heat treatment of the first mixture is performed to obtain a first heat-treated product containing the semiconductor composite nanoparticles. The temperature of the first heat treatment may be, for example, 200° C. or higher and 320° C. or lower. The first heat treatment may include: the temperature raising step of raising the temperature of the first mixture to a temperature in a range of 200° C. or higher and 320° C. or lower; and the synthesis step of performing a heat treatment of the first mixture at a temperature in a range of 200° C. or higher and 320° C. or lower for a predetermined time.

The range to which the temperature is raised in the temperature raising step of the first heat treatment step may be 200° C. or higher and 320° C. or lower, preferably 230° C. or higher and 290° C. or lower. A temperature increase rate may be adjusted such that the highest temperature during the temperature raising does not exceed the intended temperature, and it may be, for example, 1° C./min or higher and 50° C./min or lower.

The temperature of the heat treatment in the synthesis step of the first heat treatment step may be 200° C. or higher and 320° C. or lower, preferably 230° C. or higher and 290° C. or lower. The duration of the heat treatment in the synthesis step may be, for example, 3 seconds or longer, preferably 1 minute or longer, 10 minutes or longer, 30 minutes or longer, 60 minutes or longer, or 90 minutes or longer. Further, the duration of the heat treatment may be, for example, 300 minutes or shorter, preferably 180 minutes or shorter, or 150 minutes or shorter. The duration of the heat treatment in the synthesis step is defined that it starts at the time when the temperature reaches a temperature set in the above-described range (e.g., at the time when the temperature reaches 250° C. in a case where the set temperature is 250° C.), and ends at the time when an operation for lowering the temperature is carried out. By the synthesis step, a dispersion containing the semiconductor composite nanoparticles in which a compound containing Ga and S is disposed on the surface of the semiconductor composite nanoparticle may be obtained.

The atmosphere of the first heat treatment is preferably an inert gas atmosphere, particularly an argon atmosphere or a nitrogen atmosphere. By using an inert gas atmosphere, the generation of an oxide as a by-product as well as the oxidation of the surfaces of the resulting semiconductor composite nanoparticles may be reduced or prevented more efficiently.

The method of producing semiconductor nanoparticles may further include, after the above-described synthesis step, the cooling step of lowering the temperature of a dispersion containing the resulting semiconductor composite nanoparticles. The cooling step starts at the time when an operation for lowering the temperature is carried out, and ends at the time when the dispersion is cooled to 50° C. or lower. The cooling step may include the duration in which the lowering rate is 50° C./min or more. Specifically, the lowering rate may be 50° C./min after the operation for lowering the temperature is carried out and at the time when the cooling is started.

The atmosphere of the cooling step is preferably an inert gas atmosphere, particularly an argon atmosphere or a nitrogen atmosphere. By using an inert gas atmosphere, the generation of an oxide as a by-product as well as the oxidation of the surfaces of the resulting semiconductor composite nanoparticles may be reduced or prevented.

In the third step, a second heat-treated product containing desired semiconductor nanoparticles (second semiconductor nanoparticles) is obtained by performing a second heat treatment of a second mixture that contains the semiconductor composite particles obtained in the second step and a gallium halide. By this second heat treatment of the second mixture that contains the semiconductor composite particles and the gallium halide, second semiconductor nanoparticles having further improved band-edge emission purity and internal quantum yield may be produced.

The second mixture can be provided by mixing the semiconductor composite particles obtained in the second step with a gallium halide. The second mixture may further contain an organic solvent. Examples of the organic solvent contained in the second mixture are the same as or similar to those exemplified above for the second step. When the second mixture contains an organic solvent, the second mixture may be provided such that the concentration of the semiconductor composite particles therein is, for example, 5.0× 10⁻⁸ mol/L or higher, or 5.0×10⁻⁶ mol/L or lower, preferably 1.0×10⁻⁷ mol/L or higher, or 2.5×10⁻⁶ mol/L or lower. The concentration of the semiconductor composite particles is set based on the amount of substance as particles.

Examples of the gallium halide in the second mixture include gallium fluoride, gallium chloride, gallium bromide, and gallium iodide, and the second mixture may contain at least one selected from the group consisting of these gallium halides. Further, the gallium halide may contain at least gallium chloride. When the gallium halide contains gallium chloride, the content of gallium chloride in the gallium halide may be, for example, 70% by mole or higher, preferably 90% by mole or higher, or 95% by mole or higher, but preferably 100% by mole or lower, or lower than 100% by mole. The gallium halide may be used singly, or in combination of two or more thereof.

In the second mixture, a content molar ratio of the gallium halide with respect to the semiconductor composite particles may be, for example, 0.01 or higher and 50 or lower, preferably 0.1 or higher and 10 or lower.

The temperature of the second heat treatment performed in the third step may be, for example, 200° C. or higher and 320° C. or lower. The second heat treatment step may include: the temperature raising step of raising the temperature of the second mixture to a temperature in a range of 200° C. or higher and 320° C. or lower; and the modification step of performing a heat treatment of the second mixture at a temperature in a range of 200° C. or higher and 320° C. or lower for a predetermined time.

The second heat treatment may further include, prior to the temperature raising step, the pre-heat treatment step of performing a heat treatment of the second mixture at a temperature of 60° C. or higher and 100° C. or lower. The temperature of the heat treatment in the pre-heat treatment step may be, for example, 70° C. or higher and 90° C. or lower. The duration of the heat treatment in the pre-heat treatment step may be, for example, 1 minute or longer and 2 hours or shorter, preferably 5 minutes or longer, or 1 hour or shorter.

The range to which the temperature is raised in the temperature raising step of the second heat treatment may be 200° C. or higher and 320° C. or lower, preferably 230° C. or higher and 290° C. or lower. A temperature increase rate may be adjusted such that the highest temperature during the temperature raising does not exceed the intended temperature, and it may be, for example, 1° C./min or higher and 50° C./min or lower.

The temperature of the heat treatment in the modification step of the second heat treatment may be 200° C. or higher and 320° C. or lower, preferably 230° C. or higher and 290° C. or lower. The duration of the heat treatment in the modification step may be, for example, 3 seconds or longer, preferably 1 minute or longer, 10 minutes or longer, 30 minutes or longer, 60 minutes or longer, or 90 minutes or longer. Further, the duration of the heat treatment may be, for example, 300 minutes or shorter, preferably 180 minutes or shorter, or 150 minutes or shorter. The duration of the heat treatment in the modification step is defined that it starts at the time when the temperature reaches a temperature set in the above-described range (e.g., at the time when the temperature reaches 250° C. in a case where the set temperature is 250° C.), and ends at the time when an operation for lowering the temperature is carried out.

The atmosphere of the second heat treatment step is preferably an inert gas atmosphere, particularly an argon atmosphere or a nitrogen atmosphere. By using an inert gas atmosphere, the generation of an oxide as a by-product as well as the oxidation of the surfaces of the resulting second semiconductor nanoparticles may be reduced or prevented.

The method of producing semiconductor nanoparticles may further include, after the above-described modification step, the cooling step of lowering the temperature of a dispersion containing the resulting second semiconductor nanoparticles. The cooling step starts at the time when an operation for lowering the temperature is carried out, and ends at the time when the dispersion is cooled to 50° C. or lower.

The cooling step may include a period in which the temperature lowering rate is 50° C./min or higher. The temperature lowering rate may be 50° C./min or higher particularly at the time when the temperature starts to decrease after the operation for lowering the temperature is carried out.

The atmosphere of the cooling step is preferably an inert gas atmosphere, particularly an argon atmosphere or a nitrogen atmosphere. By using an inert gas atmosphere, the generation of an oxide as a by-product as well as the oxidation of the surfaces of the resulting second semiconductor nanoparticles may be reduced or prevented more efficiently.

The second semiconductor nanoparticles contained in the second heat-treated product are formed by disposing a compound containing Ga and S on the surfaces of the first semiconductor nanoparticles, and subsequently performing a surface treatment with the gallium halide. The second semiconductor nanoparticles may be configured such that the second semiconductor is disposed on the surfaces of first semiconductor-containing portions of the first semiconductor nanoparticles and the compound containing Ga and S is further disposed thereon, or may be configured such that the second semiconductor and the compound containing Ga and S are integrally disposed on the surfaces of the first semiconductor-containing portions. In other words, the second semiconductor nanoparticles may be configured such that a deposit containing the second semiconductor is disposed on the surfaces of particles containing the first semiconductor and a deposit containing Ga and S is disposed on the surfaces of the particles containing the first semiconductor or on the deposit containing the second semiconductor, or may be configured such that the particles containing the first semiconductor are covered with a deposit containing the second semiconductor and the covered surfaces of the particles are further covered with a deposit containing Ga and S. Moreover, the second semiconductor nanoparticles may have a core-shell structure in which, for example, a particle containing the first semiconductor constitutes a core and the deposit containing the second semiconductor and the deposit containing Ga and S constitute a shell that is disposed on the surface of the core. The deposit containing the second semiconductor and the deposit containing Ga and S may be laminated to form the shell, or the second semiconductor and the compound containing Ga and S may be integrated to form the shell.

The ratio of the average particle size of the second semiconductor nanoparticles with respect to the average particle size of the first semiconductor nanoparticles may be, for example, 1 to 5, preferably 1.01 or higher, 1.05 or higher, 1.08 or higher, 1.1 or higher, or 1.2 or higher, but preferably 2 or lower, 1.8 or lower, or 1.5 or lower.

The method of producing semiconductor nanoparticles may also include the separation step of separating the second semiconductor nanoparticles from the second heat-treated product obtained by the second heat treatment, and may further include the purification step as required. In the separation step, for example, the second heat-treated product containing the second semiconductor nanoparticles may be centrifuged to recover the resulting precipitate containing the second semiconductor nanoparticles. In the purification step, for example, an appropriate organic solvent such as an alcohol may be added to the precipitate obtained in the separation step, and the resultant may be subsequently centrifuged to recover the second semiconductor nanoparticles as a precipitate. That is, the purification step may include; mixing the second heat-treated product with an organic solvent to obtain a third mixture, centrifuging the third mixture, and followed by recovering the second semiconductor nanoparticles as a precipitate. In the method of producing semiconductor nanoparticles, the purification step of adding an organic solvent and centrifuging may be performed multiple times, if necessary.

The organic solvent used in the purification step may contain an alcohol solvent. The alcohol solvent used in the purification step may be, for example, a lower alcohol having 1 to 5 carbon atoms, such as methanol, ethanol, n-propyl alcohol, isopropyl alcohol, n-butyl alcohol, isobutyl alcohol, n-amyl alcohol, or isoamyl alcohol. The fluid amount of the organic solvent used in the purification step may be, for example, 0.1 or higher and 10 or lower, preferably 0.4 or higher and 2 or lower, in terms of volume ratio with respect to the fluid amount of the second mixture.

In the method of producing semiconductor nanoparticles, a reduction in the internal quantum yield in the purification step can be reduced or suppressed. This is believed to be because, for example, by disposing a compound containing Ga and S on the surfaces of the first semiconductor nanoparticles in the second step, the durability against the organic solvent used in the purification step is improved. The improvement in the durability in the purification step can be evaluated based on, for example, a ratio of the internal quantum yield of the semiconductor nanoparticles obtained after the centrifugation with respect to the internal quantum yield of the semiconductor nanoparticles contained in the second heat-treated product. The ratio of the internal quantum yield of the semiconductor nanoparticles obtained after the centrifugation in the purification step with respect to the internal quantum yield of the semiconductor nanoparticles contained in the second heat-treated product may be, for example, 0.7 to 1.1, preferably 0.8 or higher, or 0.9 or higher, but preferably 1.08 or lower, or 1.06 or lower.

In the separation step of the method of producing semiconductor nanoparticles, the second semiconductor nanoparticles may be recovered by vaporizing the organic solvent from the second heat-treated product. The second semiconductor nanoparticles recovered by the separation step and the purification step may be dried by, for example, vacuum degassing, air drying, or a combination of vacuum degassing and air drying. The air drying may be performed by, for example, leaving the second semiconductor nanoparticles in the atmosphere at normal temperature and normal pressure and, in this case, the second semiconductor nanoparticles may be left to stand for 20 hours or longer, for example, about 30 hours. Further, the recovered precipitate may be dispersed in an appropriate organic solvent. When the precipitate is dispersed in an organic solvent, for example, a halogen-based solvent such as chloroform, dichloromethane, dichloroethane, trichloroethane, or tetrachloroethane, or a hydrocarbon-based solvent such as toluene, cyclohexane, hexane, pentane, or octane may be used as the organic solvent. From the standpoint of internal quantum yield, the organic solvent used for dispersing the precipitate may be a halogen-based solvent.

### First Semiconductor Nanoparticles

The first semiconductor nanoparticles contained in the first mixture contain: a first semiconductor which contains Ag, In, Ga, and S; and a second semiconductor which is disposed on the surface of the first semiconductor and contains Ga and S. In the first semiconductor nanoparticles, the crystal structure of the first semiconductor existing in near the central parts may be substantially tetragonal (chalcopyrite structure), and the second semiconductor disposed on the surfaces of the first semiconductor nanoparticles may have a crystal structure with few Ga defects (e.g., Ga-deficient parts). The second semiconductor may be a semiconductor having a higher Ga composition ratio than the first semiconductor, a semiconductor having a lower Ag composition ratio than the first semiconductor, or a semiconductor composed of substantially Ga and S. Further, in the first semiconductor nanoparticles, a deposit containing the second semiconductor may be disposed on the surfaces of particles containing the first semiconductor, and the particles containing the first semiconductor may be covered with the deposit containing the second semiconductor. Moreover, the first semiconductor nanoparticles may have a core-shell structure in which, for example, a particle containing the first semiconductor constitutes a core and the deposit containing the second semiconductor is disposed as a shell on the surface of the core. With regard to the details of the first semiconductor nanoparticles and a production method thereof, reference can be made to, for example, WO 2022/191032.

The first semiconductor constituting the semiconductor nanoparticles contains Ag, In, Ga, and S. Generally, a semiconductor that contains Ag, In, and S, and has a tetragonal, hexagonal, or orthorhombic crystal structure is introduced in literature and the like as a semiconductor represented by a composition formula AgInS₂. However, such a semiconductor does not actually have a stoichiometric composition represented by the above-described general formula and, particularly, the ratio (Ag/In+Ga) of the number of Ag atoms with respect to the number of In and Ga atoms may be lower than 1, or conversely, higher than 1. In addition, a sum of the number of Ag atoms and the number of In and Ga atoms is not always equal to the number of S atoms. Therefore, in the present specification, where it is irrelevant whether a semiconductor containing specific elements has a stoichiometric composition or not, the composition of the semiconductor is represented by a formula in which the constituent elements are connected by “—” as in Ag—In—Ga—S. Accordingly, the first semiconductor nanoparticles according to the present embodiment may be considered to have a semiconductor composition of, for example, Ag—In—S, or Ag—In—Ga—S or Ag—Ga—S where In that is a Group 13 element is partially or entirely Ga that is also a Group 13 element.

Of the first semiconductor containing the above-described elements, a semiconductor having a hexagonal crystal structure is a wurtzite-type semiconductor, and a semiconductor having a tetragonal crystal structure is a chalcopyrite-type semiconductor. The crystal structure is identified by, for example, measuring the X-ray diffraction (XRD) pattern obtained by XRD analysis. Specifically, an XRD pattern obtained from the first semiconductor is compared with known XRD patterns of semiconductor nanoparticles represented by a composition AgInS₂, or with XRD patterns determined by simulation using crystal structure parameters. If the pattern of the first semiconductor corresponds to any of the known patterns and simulated patterns, the crystal structure of the semiconductor nanoparticles according to the present embodiment is said to be that of the corresponding known or simulated pattern.

An aggregate of the semiconductor nanoparticles may contain a mixture of semiconductor nanoparticles that contain first semiconductors having different crystal structures. In this case, peaks derived from the plural kinds of crystal structures are observed in the XRD pattern. In the semiconductor nanoparticles of an embodiment, the first semiconductor may be substantially composed of tetragonal crystals, and a peak corresponding to the tetragonal crystals is observed, while substantially no peak derived from other crystal structure may be observed.

In the composition of the first semiconductor, a total content ratio of Ag may be, for example, 10% by mole or higher and 30% by mole or lower, and it is preferably 15% by mole or higher and 25% by mole or lower. In the composition of the first semiconductor, a total content ratio of In and Ga may be, for example, 15% by mole or higher and 35% by mole or lower, and it is preferably 20% by mole or higher and 30% by mole or lower. In the composition of the first semiconductor, a total content ratio of S may be, for example, 35% by mole or higher and 55% by mole or lower, and it is preferably 40% by mole or higher and 55% by mole or lower.

The first semiconductor contains at least Ag that may be partially substituted such that the first semiconductor further contains at least one of Cu, Au, or an alkali metal, and may be substantially composed of Ag. The term “substantially” used herein indicates that a ratio of the number of atoms of elements other than Ag is, for example, 10% or lower, preferably 5% or lower, more preferably 1% or lower, with respect to a total number of atoms of Ag and elements other than Ag. Further, the first semiconductor may substantially contain Ag and an alkali metal (hereinafter also referred to as “M^{a}”) as constituent elements. The term “substantially” used herein indicates that a ratio of a number of elements other than Ag and the alkaline metal is, for example, 10% or lower, preferably 5% or lower, more preferably 1% or lower, with respect to a total number of atoms of Ag and the alkali metal, and elements other than Ag and the alkali metal. Examples of the alkali metal include lithium (Li), sodium (Na), potassium (K), rubidium (Rb), and cesium (Cs). The alkali metal may be a monovalent cation in the same manner as or similar manner to Ag and, therefore, may partially substitute Ag in the composition of the first semiconductor. Particularly, Li is preferably used because it has substantially the same ionic radius as Ag. Partial substitution of Ag in the composition of the first semiconductor leads to, for example, a widened band gap and a shift of the emission peak wavelength to the shorter wavelength side. In addition, it is believed that, although the details are unclear, the lattice defects of the first semiconductor are reduced and the internal quantum yield of band-edge emission is improved. When the first semiconductor contains an alkali metal, the first semiconductor may contain at least Li.

When the first semiconductor contains Ag and an alkali metal (M^{a}), a content ratio of the alkali metal in the composition of the first semiconductor may be, for example, higher than 0% by mole and lower than 30% by mole, preferably 1% by mole or higher and 25% by mole or lower. Further, in the composition of the first semiconductor, a ratio (M^{a}/(Ag+M^{a})) of the number of alkali metal (M^{a}) atoms with respect to a total of the number of Ag atoms and the number of alkali metal (M^{a}) atoms may be, for example, lower than 1, preferably 0.8 or lower, more preferably 0.4 or lower, still more preferably 0.2 or lower. This ratio may be, for example, higher than 0, preferably 0.05 or higher, more preferably 0.1 or higher.

The first semiconductor contains In and Ga that may be partially substituted such that the first semiconductor further contains at least one of Al or Tl, and may be substantially composed of In and Ga. The term “substantially” used herein indicates that a ratio of the number of atoms of elements other than In and Ga is, for example, 10% or lower, preferably 5% or lower, more preferably 1% or lower, with respect to a total number of atoms of In, Ga, and elements other than In and Ga.

In the first semiconductor, a ratio (In/(In+Ga)) of the number of In atoms with respect to a total number of In and Ga atoms may be, for example, 0.01 or higher and lower than 1, and it is preferably 0.1 or higher and 0.99 or lower. When the ratio of the number of In atoms with respect to a total number of In and Ga atoms is in this predetermined range, a short emission peak wavelength (e.g., 545 nm or shorter) may be obtained. Further, a ratio (Ag/(In+Ga)) of the number of Ag atoms with respect to a total number of In and Ga atoms may be, for example, 0.3 or higher and 1.2 or lower, preferably 0.5 or higher and 1.1 or lower. A ratio (S/(Ag+In+Ga)) of the number of S atoms with respect to a total number of atoms of Ag, In, and Ga is, for example, 0.8 or higher and 1.5 or lower, preferably 0.9 or higher and 1.2 or lower.

The first semiconductor contains S that may be partially substituted such that the first semiconductor further contains at least one of Se and Te, and may be substantially composed of S. The term “substantially” used herein indicates that a ratio of the number of atoms of elements other than S is, for example, 10% or lower, preferably 5% or lower, more preferably 1% or lower, with respect to a total number of atoms S and elements other than S.

The first semiconductor may be substantially composed of Ag, In, Ga, S, and the above-described elements partially substituting these elements. The term “substantially” used herein takes into consideration that elements other than Ag, In, Ga, S, and the elements partially substituting these elements may be unavoidably incorporated due to, for example, contamination with impurities.

The first semiconductor may have a composition represented by, for example, the following formula (1):

$${( {Ag}_{p} {M}_{( 1 - p )}^{a} )}_{q} {In}_{r} {Ga}_{( 1 - r )} {S}_{( q + 3 ) / 2} \qquad ( 1 )$$

wherein, p, q, and r satisfy 0<p≤1, 0.20<q≤1.2, and 0<r<1; and M^{a} represents an alkali metal.

A second semiconductor may be disposed on the surfaces of the semiconductor nanoparticles. The second semiconductor may contain a semiconductor having a larger band-gap energy than that of the first semiconductor. The composition of the second semiconductor may have a higher Ga molar content than the composition of the first semiconductor. A ratio of the Ga molar content in the composition of the second semiconductor with respect to the Ga molar content in the composition of the first semiconductor may be, for example, higher than 1 and 5 or lower, preferably 1.1 or higher and 3 or lower.

Further, the composition of the second semiconductor may have a lower Ag molar content than the composition of the first semiconductor. A ratio of the Ag molar content in the composition of the second semiconductor with respect to the Ag molar content in the composition of the first semiconductor may be, for example, 0.1 or higher and 0.7 or lower, preferably 0.2 or higher, or 0.5 or lower. The ratio of the Ag molar content in the composition of the second semiconductor may be, for example, 0.5 or lower, preferably 0.2 or lower, 0.1 or lower, or substantially 0. The term “substantially” used herein indicates that, when a total number of atoms of all elements contained in the second semiconductor is taken as 100%, a ratio of the number of Ag atoms is, for example, 10% or lower, preferably 5% or lower, more preferably 1% or lower.

In the semiconductor nanoparticles, the second semiconductor disposed on the surface may contain a semiconductor containing Ga and S. This semiconductor containing Ga and S may be a semiconductor having a larger band-gap energy than that of the first semiconductor.

In the composition of the semiconductor containing Ga and S that is contained in the second semiconductor, Ga may be partially substituted with at least one Group 13 element selected from the group consisting of boron (B), aluminum (Al), indium (In), and thallium (Tl). Further, S may be partially substituted with at least one Group 16 element selected from the group consisting of oxygen (O), selenium (Se), tellurium (Te), and polonium (Po).

The semiconductor containing Ga and S may be a semiconductor substantially composed of Ga and S. The term “substantially” used herein indicates that, when a total number of atoms of all elements contained in the semiconductor containing Ga and S is taken as 100%, a ratio of the number of atoms of elements other than Ga and S is, for example, 10% or lower, preferably 5% or lower, more preferably 1% or lower.

The semiconductor containing Ga and S may be formed by selecting its composition and the like in accordance with the band-gap energy of the above-described first semiconductor. Alternatively, when the composition and the like of the semiconductor containing Ga and S are predetermined, the first semiconductor may be designed such that the band-gap energy of the first semiconductor is smaller than that of the semiconductor containing Ga and S. Generally, a semiconductor composed of Ag—In—S has a band-gap energy of 1.8 eV or higher and 1.9 eV or lower.

Specifically, the semiconductor containing Ga and S may have a band-gap energy of, for example, 2.0 eV or higher and 5.0 eV or lower, particularly 2.5 eV or higher and 5.0 eV or lower. The band-gap energy of the semiconductor containing Ga and S may be larger than that of the first semiconductor by, for example, about 0.1 eV or higher and 3.0 eV or lower, particularly about 0.3 eV or higher and 3.0 eV or lower, more particularly about 0.5 eV or higher and 1.0 eV or lower. When the difference between the band-gap energy of the semiconductor containing Ga and S and the band-gap energy of the first semiconductor is equal to or greater than the above-described lower limit value, the ratio of emission other than band-edge emission tends to be reduced, and the ratio of band-edge emission tends to be increased, in the emission from the semiconductor nanoparticles.

The second semiconductor may contain an oxygen (O) atom. An oxygen atom-containing semiconductor tends to have a larger band-gap energy than the above-described first semiconductor. The form of an oxygen atom-containing semiconductor in the second semiconductor is not clear; however, it may be, for example, Ga—O—S or Ga₂O₃.

The second semiconductor may further contain an alkali metal (M^{a}) in addition to Ga and S. The alkali metal contained in the second semiconductor may contain at least lithium. When the second semiconductor contains an alkali metal, a ratio of the number of alkali metal atoms with respect to a sum of the number of alkali metal atoms and the number of Ga atoms may be, for example, 0.01 or higher and lower than 1, or 0.1 or higher and 0.9 or lower. Further, a ratio of the number of S atoms with respect to a sum of the number of alkali metal atoms and the number of Ga atoms may be, for example, 0.25 or higher and 0.75 or lower.

The second semiconductor may have a crystal system conforming to that of the first semiconductor, and may have a lattice constant that is the same as or close to that of the first semiconductor. The second semiconductor which has a crystal system conforming to that of the first semiconductor and a lattice constant close to that of the first semiconductor (including a case where a multiple of the lattice constant of the second semiconductor is similar to the lattice constant of the first semiconductor) may preferably cover the periphery of the first semiconductor. For example, the first semiconductor generally has a tetragonal crystal system, and examples of a crystal system conforming thereto include a tetragonal system and an orthorhombic crystal system. When Ag—In—S has a tetragonal crystal system, it is preferred that the lattice constants of its constituent elements be 0.5828 nm, 0.5828 nm, and 1.119 nm, respectively; and that the second semiconductor covering this Ag—In—S has a tetragonal or orthorhombic crystal system, and its lattice constants or multiple thereof be close to the lattice constants of Ag—In—S. Alternatively, the second semiconductor may be amorphous.

The second semiconductor preferably does not form a solid solution with the first semiconductor. If the second semiconductor forms a solid solution with the first semiconductor, because the second semiconductor and the first semiconductor are integrated together, the mechanism of the present embodiment in which the second semiconductor is disposed on the surfaces of the semiconductor nanoparticles and the band-edge emission is thereby obtained cannot be attained. For example, it has been confirmed that band-edge emission cannot be obtained from the semiconductor nanoparticles even when zinc sulfide (Zn—S) having a stoichiometric or non-stoichiometric composition is disposed on the surfaces of the semiconductor nanoparticles containing the first semiconductor composed of Ag—In—S. Zn—S, in its relationship with Ag—In—S, satisfies the above-described conditions in terms of band-gap energy, and gives a type-I band alignment. Nevertheless, band-edge emission was not obtained from the above-described specific semiconductor, and it is surmised that the reason for this is because the first semiconductor and Zn—S formed a solid solution.

The semiconductor nanoparticles may have an average particle size of, for example, 50 nm or smaller. From the standpoints of the ease of production and the internal quantum yield of band-edge emission, the average particle size is preferably in a range of 1 nm or larger and 20 nm or smaller, more preferably 1.6 nm or larger and 8 nm or smaller, particularly preferably 2 nm or larger and 7.5 nm or smaller.

The average particle size of the first semiconductor nanoparticles may be determined from, for example, a TEM image captured using a transmission electron microscope (TEM). The particle size of individual particle specifically refers to the length of the longest line segment among those line segments that exist inside the particle observed in a TEM image and connect two arbitrary points on the circumference of the particle. A specific method of measuring the particle size of individual particle will be described below.

In the first semiconductor nanoparticles, the parts containing the first semiconductor may be in a particulate form and have an average particle size of, for example, 10 nm or smaller, particularly 8 nm or smaller, or smaller than 7.5 nm. The average particle size of the parts containing the first semiconductor may be in a range of, for example, 1.5 nm to 10 nm, preferably 1.5 nm or larger but smaller than 8 nm, or 1.5 nm or larger but smaller than 7.5 nm. When the average particle size of the parts containing the first semiconductor is equal to or smaller than the above-described upper limit value, a quantum size effect is likely to be obtained.

In the first semiconductor nanoparticles, the parts containing the second semiconductor may have a thickness in a range of 0.1 nm or larger and 20 nm or smaller, particularly in a range of 0.3 nm or larger and 5 nm or smaller. When the thickness of the parts containing the second semiconductor is equal to or larger than the above-described lower limit value, the effect provided by disposing the second semiconductor on the first semiconductor nanoparticles is sufficiently exerted, so that band-edge emission is likely to be obtained.

The first semiconductor nanoparticles preferably have a substantially tetragonal crystal structure. The crystal structure is identified by, for example, measuring the X-ray diffraction (XRD) pattern obtained by XRD analysis in the same manner as or similar manner to described above. The term “substantially tetragonal crystal” used herein indicates that a ratio of the height of a peak at about 48°, which represents hexagonal and orthorhombic crystals, with respect to the height of a main peak at about 26°, which represents a tetragonal crystal, is, for example, 10% or smaller, or 5% or smaller.

The first semiconductor nanoparticles, when irradiated with light having a wavelength range of 380 nm or longer and 545 nm or shorter, may exhibit band-edge emission having an emission peak wavelength in a wavelength range of 475 nm or longer and 560 nm or shorter, and the range of the emission peak wavelength may be preferably 510 nm or longer and 550 nm or shorter, more preferably 525 nm or longer and 535 nm or shorter. Further, in the emission spectrum of the first semiconductor nanoparticles, the full width at half maximum may be, for example, 45 nm or smaller, preferably 40 nm or smaller, or 30 nm or smaller. The full width at half maximum may be, for example, 15 nm or larger. Moreover, the emission lifetime of a main component (band-edge emission) is preferably 200 ns or shorter. The details of “the emission lifetime” will be described below.

The emission of the first semiconductor nanoparticles may include defect emission (e.g., donor-acceptor emission) in addition to band-edge emission; however, the emission is preferably substantially band-edge emission alone. Defect emission generally has a longer emission lifetime and a broader spectrum with a peak on the longer wavelength side as compared to band-edge emission. The expression “substantially band-edge emission alone” used herein means that the purity of the band-edge emission component in the emission spectrum (hereinafter, also referred to as “band-edge emission purity”) is 40% or higher, and this purity is preferably 70% or higher, more preferably 80% or higher, still more preferably 90% or higher, particularly preferably 95% or higher. The purity of the band-edge emission component may be, for example, 100% or lower, lower than 100%, or 99% or lower. The details of “purity of the band-edge emission component” will be described below.

The internal quantum yield of the band-edge emission is defined as a value obtained by multiplying the internal quantum yield, which is measured using a quantum yield measuring device at a temperature of 25° C. and calculated under the any of three following conditions by the above-described purity of the band-edge emission component, and dividing the product by 100. The three conditions are (i) an excitation light wavelength of 450 nm and a fluorescence wavelength range of 470 nm or longer and 900 nm or shorter, (ii) an excitation light wavelength of 365 nm and a fluorescence wavelength range of 450 nm or longer and 950 nm or shorter, or (iii) an excitation light wavelength of 450 nm and a fluorescence wavelength range of 500 nm or longer and 950 nm or shorter. The internal quantum yield of the band-edge emission of the semiconductor nanoparticles is, for example, 15% or higher, preferably 50% or higher, more preferably 60% or higher, still more preferably 70% or higher, particularly preferably 80% or higher.

The peak position of the band-edge emission by the first semiconductor nanoparticles may be shifted by modifying the particle size of the semiconductor nanoparticles. For example, when the particle size of the semiconductor nanoparticles is reduced, the peak wavelength of the band-edge emission tends to shift to the shorter wavelength side. A further reduction in the particle size of the first semiconductor nanoparticles tends to further reduce the spectral full width at half maximum of the band-edge emission.

When the first semiconductor nanoparticles exhibit defect emission in addition to band-edge emission, the intensity ratio of the band-edge emission may be, for example, 0.75 or higher, and it is preferably 0.85 or higher, more preferably 0.9 or higher, particularly preferably 0.93 or higher. The upper limit of the intensity ratio of the band-edge emission may be, for example, 1 or lower, lower than 1, or 0.99 or lower. The details of the intensity ratio of the band-edge emission will be described below.

The first semiconductor nanoparticles preferably exhibit an absorption or excitation spectrum (also referred to as “fluorescence excitation spectrum”) with an exciton peak. An exciton peak is a peak resulting from exciton formation, and the appearance of this peak in an absorption or excitation spectrum means that the particles have a small particle size distribution and few crystal defects, and are thus suitable for band-edge emission. A sharper exciton peak means that an aggregate of the semiconductor nanoparticles contains a greater amount of particles having a uniform particle size with few crystal defects. Accordingly, it is expected that the semiconductor nanoparticles exhibit emission with a narrower full width at half maximum and an improved emission efficiency. In the absorption or excitation spectrum of the first semiconductor nanoparticles of the present embodiment, an exciton peak is observed, for example, in a range of 400 nm or longer and 550 nm or shorter, preferably 430 nm or longer and 500 nm or shorter. The excitation spectrum for checking the presence or absence of an exciton peak may be measured by setting the observation wavelength around the peak wavelength.

The surfaces of the first semiconductor nanoparticles may be modified with a surface modifier. Specific examples of the surface modifier include an amino alcohol having 2 to 20 carbon atoms, an ionic surface modifier, a nonionic surface modifier, a nitrogen-containing compound containing a hydrocarbon group having 4 to 20 carbon atoms, a sulfur-containing compound containing a hydrocarbon group having 4 to 20 carbon atoms, an oxygen-containing compound containing a hydrocarbon group having 4 to 20 carbon atoms, a phosphorus-containing compound containing a hydrocarbon group having 4 to 20 carbon atoms, and a halide of a Group 2, 12, or 13 element. These surface modifiers may be used singly, or in combination of two or more different kinds thereof.

The surfaces of the first semiconductor nanoparticles may be modified with a gallium halide. By modifying the surfaces of the first semiconductor nanoparticles with a gallium halide, the internal quantum yield of the band-edge emission is improved. Specific examples of the gallium halide include gallium chloride, gallium fluoride, gallium bromide, and gallium iodide.

The surface of the second semiconductor on the first semiconductor nanoparticles may be modified with a gallium halide. By modifying the surface of the second semiconductor on the first semiconductor nanoparticles with a gallium halide, the internal quantum yield of the band-edge emission is improved.

The emission of the first semiconductor nanoparticles surface-modified with a gallium halide may include defect emission (donor-acceptor emission) in addition to band-edge emission; however, the emission is preferably substantially band-edge emission alone. The expression “substantially band-edge emission alone” used herein means that, as described for the above-described first semiconductor nanoparticles, the purity of the band-edge emission component is preferably 70% or higher, more preferably 80% or higher, still more preferably 90% or higher, particularly preferably 95% or higher.

The measurement of the internal quantum yield of the band-edge emission of the first semiconductor nanoparticles surface-modified with a gallium halide is as described for the above-described first semiconductor nanoparticles, and the internal quantum yield of the band-edge emission is, for example, 15% or higher, preferably 50% or higher, more preferably 60% or higher, still more preferably 70% or higher, particularly preferably 80% or higher.

### Method of Producing First Semiconductor Nanoparticles

The method of producing the first semiconductor nanoparticles includes a fourth step of performing a fourth heat treatment of a fourth mixture, which contains a silver (Ag) salt, an indium (In) salt, a compound having a gallium-sulfur (Ga—S) bond, a gallium halide, and an organic solvent, to obtain first semiconductor nanoparticles. As required, the method of producing the first semiconductor nanoparticles may further include other steps in addition to the fourth step.

### Fourth Step

The fourth step may include: a fourth mixing step of obtaining a fourth mixture that contains a Ag salt, an In salt, a compound having a Ga—S bond, a gallium halide, and an organic solvent; and a fourth heat treatment step of performing a fourth heat treatment to the fourth mixture to obtain first semiconductor nanoparticles.

By using a compound having a Ga—S bond as a supply source of Ga and S that are included in the composition of the first semiconductor nanoparticles to be produced, it is made easy to control the composition of the first semiconductor nanoparticles. In addition, by using a gallium halide, it is made easy to control the particle size of the first semiconductor nanoparticles to be produced. Accordingly, it may be believed that the first semiconductor nanoparticles that exhibit band-edge emission with a high purity may be efficiently produced by a one-pot process.

In the fourth mixing step, a fourth mixture is provided by mixing a Ag salt, an In salt, a compound having a Ga—S bond, a gallium halide, and an organic solvent. A mixing method in the fourth mixing step may be selected as appropriate from those mixing methods that are usually employed.

The Ag salt and the In salt in the fourth mixture may each be either an organic acid salt or an inorganic acid salt. Specifically, examples of the inorganic acid salt include nitrates, sulfates, and hydrochlorides, and examples of the organic acid salt include formates, acetates, oxalates, acetylacetonates, and sulfonates. The Ag salt and the In salt may each be preferably at least one selected from the group consisting of these acid salts. Also, the Ag salt and the In salt may each be more preferably at least one selected from the group consisting of organic acid salts such as acetates and acetylacetonates because these salts are highly soluble in organic solvents and thus allow reaction to proceed more uniformly. The fourth mixture may contain each of the Ag salt and the In salt singly, in combination of one or more of the Ag salts and one or more of the In salts, or in combination of two or more of the Ag salts and two or more of the In salts.

The Ag salt in the fourth mixture may contain a compound having an Ag—S bond because this may suppress the generation of silver sulfide as a by-product in the below-described fourth heat treatment step. The details of the compound having an Ag—S bond are the same as or similar to those of the compound having an Ag—S bond in the above-described first mixture.

The In salt in the fourth mixture may contain a compound having an In—S bond. The In—S bond may be any of a covalent bond, an ionic bond, a coordinate bond, and the like. Examples of the compound having an In—S bond include In salts of sulfur-containing compounds, and the compound having an In—S bond may be an organic acid salt, inorganic acid salt, organic metal compound, or the like of In. Examples of the sulfur-containing compounds specifically include thiocarbamic acids, dithiocarbamic acids, thiocarbonic acid esters, dithiocarbonic acid esters (xanthic acid), trithiocarbonic acid esters, thiocarboxylic acids, dithiocarboxylic acids, and derivatives thereof. Thereamong, at least one selected from the group consisting of xanthic acid and derivatives thereof is preferred because these compounds are decomposed at a relatively low temperature. Specific examples of the sulfur-containing compounds are the same as or similar to described above. Specific examples of the compound having an In—S bond include indium tris(dimethyldithiocarbamate), indium tris(diethyldithiocarbamate) (In(DDTC)₃), indium chloro-bis(diethyldithiocarbamate), and indium ethyl xanthate (In(EX)₃).

The details of the compound having a Ga—S bond in the fourth mixture are the same as or similar to those of the compound having a Ga—S bond in the first mixture. The details of the gallium halide in the fourth mixture are the same as or similar to those of the gallium halide in the second mixture. The details of the organic solvent in the fourth mixture are the same as or similar to those of the organic solvent in the first mixture.

A content ratio of Ag, In, Ga, and S in the fourth mixture may be selected as appropriate in accordance with the intended composition. In this case, the content ratio of Ag, In, Ga, and S does not have to conform to a stoichiometric ratio. For example, a ratio (Ga/(In+Ga)) of the number of moles of Ga with respect to a total number of moles of In and Ga may be 0.2 or higher and 0.95 or lower, 0.4 or higher and 0.9 or lower, or 0.6 or higher and 0.9 or lower. In addition, for example, a ratio (Ag/(Ag+In+Ga)) of the number of moles of Ag with respect to a total number of moles of Ag, In, and Ga may be 0.05 or higher and 0.55 or lower. Further, for example, a ratio (S/(Ag+In+Ga)) of the number of moles of S with respect to a total number of moles of Ag, In, and Ga may be 0.6 or higher and 1.6 or lower.

The fourth mixture may further contain an alkali metal salt. Examples of the alkali metal (M^{a}) include lithium (Li), sodium (Na), potassium (K), rubidium (Rb), and cesium (Cs), and the first mixture preferably contains Li because Li has an ionic radius close to that of Ag. Examples of the alkali metal salt include organic acid salts and inorganic acid salts. Specifically, examples of the inorganic acid salts include nitrates, sulfates, and hydrochlorides, and examples of the organic acid salts include acetates, acetylacetonates, and sulfonates. Thereamong, organic acid salts are preferred because they are highly soluble in organic solvents.

When the fourth mixture contains an alkali metal salt, a ratio (M^{a}/(Ag+M^{a})) of the number of alkali metal atoms with respect to a total number of Ag and alkali metal atoms may be, for example, lower than 1, and it is preferably 0.8 or lower, more preferably 0.4 or lower, still more preferably 0.2 or lower. Further, this ratio may be, for example, higher than 0, and it is preferably 0.05 or higher, more preferably 0.1 or higher.

In the fourth mixture, a content molar ratio of the gallium halide with respect to the Ag salt may be, for example, 0.01 or higher and 1 or lower and, from the viewpoint of internal quantum yield, it may be preferably 0.12 or higher and 0.45 or lower.

The concentration of the Ag salt in the fourth mixture may be, for example, 0.01 mmol/L or higher and 500 mmol/L or lower and, from the viewpoint of internal quantum yield, it may be preferably 0.05 mmol/L or higher and 100 mmol/L or lower, more preferably 0.1 mmol/L or higher and 10 mmol/L or lower.

In the fourth heat treatment step, a fourth heat treatment of the fourth mixture is performed to obtain first semiconductor nanoparticles. The temperature of the fourth heat treatment may be, for example, 200° C. or higher and 320° C. or lower. The fourth heat treatment step may include: the temperature raising step of raising the temperature of the fourth mixture to a temperature in a range of 200° C. or higher and 320° C. or lower; and the synthesis step of performing a heat treatment of the fourth mixture at a temperature in a range of 200° C. or higher and 320° C. or lower for a predetermined time.

The range to which the temperature is raised in the temperature raising step of the fourth heat treatment step may be 200° C. or higher and 320° C. or lower, preferably 230° C. or higher and 290° C. or lower. A temperature increase rate may be adjusted such that the highest temperature during the temperature raising does not exceed the intended temperature, and it is, for example, 1° C./min or higher and 50° C./min or lower.

The temperature of the heat treatment in the synthesis step of the fourth heat treatment step may be 200° C. or higher and 320° C. or lower, preferably 230° C. or higher and 290° C. or lower. The duration of the heat treatment in the synthesis step may be, for example, 3 seconds or longer, preferably 1 minute or longer, 10 minutes or longer, 30 minutes or longer, 60 minutes or longer, or 90 minutes or longer. Further, the duration of the heat treatment may be, for example, 300 minutes or shorter, preferably 180 minutes or shorter, or 150 minutes or shorter. The duration of the heat treatment in the synthesis step is defined that it starts at the time when the temperature reaches a temperature set in the above-described range (e.g., at the time when the temperature reaches 250° C. in a case where the set temperature is 250° C.), and ends at the time when an operation for lowering the temperature is carried out. By the synthesis step, a dispersion containing the first semiconductor nanoparticles may be obtained.

The atmosphere of the fourth heat treatment step is preferably an inert gas atmosphere, particularly an argon atmosphere or a nitrogen atmosphere. By using an inert gas atmosphere, the generation of an oxide as a by-product as well as the oxidation of the surfaces of the resulting semiconductor nanoparticles may be reduced or prevented more efficiently.

The method of producing the first semiconductor nanoparticles may further include, after the above-described synthesis step, the cooling step of lowering the temperature of a dispersion containing the resulting first semiconductor nanoparticles. The cooling step starts at the time when an operation for lowering the temperature is carried out, and ends at the time when the dispersion is cooled to 50° C. or lower.

From the viewpoint of suppressing the generation of silver sulfide from unreacted Ag salt, the cooling step may include a period in which the temperature lowering rate is 50° C./min or higher. The temperature lowering rate may be 50° C./min or higher particularly at the time when the temperature starts to decrease after the operation for lowering the temperature is carried out.

The atmosphere of the cooling step is preferably an inert gas atmosphere, particularly an argon atmosphere or a nitrogen atmosphere. By using an inert gas atmosphere, the generation of an oxide as a by-product as well as the oxidation of the surfaces of the resulting semiconductor nanoparticles may be reduced or prevented more efficiently.

The method of producing first semiconductor nanoparticles may also include the separation step of separating the first semiconductor nanoparticles from the dispersion, and may further include the purification step as required. The details of the separation step and the purification step are as described above.

The first semiconductor nanoparticles obtained in the above-described manner may be in the state of a dispersion or a dry powder. The first semiconductor nanoparticles may exhibit band-edge emission with a high purity. The semiconductor nanoparticles obtained by the above described producing method may be the first semiconductor nanoparticles, or semiconductor nanoparticles obtained after the below-described fifth step may be the first semiconductor nanoparticles.

The method of producing the first semiconductor nanoparticles may further include a fifth step of performing a fifth heat treatment to a fifth mixture, which contains the first semiconductor nanoparticles and a gallium halide, to obtain semiconductor nanoparticles.

### Fifth Step

The Fifth step may include: a fifth mixing step of obtaining a fifth mixture that contains the semiconductor nanoparticles obtained in the above-described fourth step and a gallium halide; and a fifth heat treatment step of performing a fifth heat treatment to the fifth mixture to obtain semiconductor nanoparticles.

By performing the fifth heat treatment of the fifth mixture that contains the first semiconductor nanoparticles and a gallium halide, semiconductor nanoparticles of which the band-edge emission purity and the internal quantum yield are further improved may be produced.

In the fifth mixing step, a fifth mixture is obtained by mixing the first semiconductor nanoparticles and a gallium halide. The fifth mixture may further contain an organic solvent. Examples of the organic solvent contained in the fifth mixture are the same as or similar to those exemplified above for the first step. When the fifth mixture contains an organic solvent, the fifth mixture may be provided such that the concentration of the first semiconductor nanoparticles therein is, for example, 5.0×10⁻⁷ mol/L or higher and 5.0×10⁻⁵ mol/L or lower, particularly 1.0×10⁻⁶ mol/L or higher, or 1.0×10⁻⁵ mol/L or lower. The concentration of the first semiconductor nanoparticles is set based on the amount of substance as particles as described above.

The details of the gallium halide in the fifth mixture are as described above. In the fifth mixture, a content molar ratio of the gallium halide with respect to the amount of substance as particles of the first semiconductor nanoparticles may be, for example, 0.01 or higher and 50 or lower, and it is preferably 0.1 or higher and 10 or lower.

In the fifth heat treatment step, a fifth heat treatment of the fifth mixture is performed to obtain semiconductor nanoparticles. The temperature of the fifth heat treatment may be, for example, 200° C. or higher and 320° C. or lower. The fifth heat treatment step may include: the temperature raising step of raising the temperature of the fifth mixture to a temperature in a range of 200° C. or higher and 320° C. or lower; and the modification step of performing a heat treatment of the fifth mixture at a temperature in a range of 200° C. or higher and 320° C. or lower for a predetermined time.

The fifth heat treatment step may further include, prior to the temperature raising step, the pre-heat treatment step of performing a heat treatment of the fifth mixture at a temperature of 60° C. or higher and 100° C. or lower. The temperature of the heat treatment in the pre-heat treatment step may be, for example, 70° C. or higher and 90° C. or lower. The duration of the heat treatment in the pre-heat treatment step may be, for example, 1 minute or longer and 2 hours or shorter, preferably 5 minutes or longer and 1 hour or shorter.

The range to which the temperature is raised in the temperature raising step of the fifth heat treatment step may be 200° C. or higher and 320° C. or lower, preferably 230° C. or higher and 290° C. or lower. A temperature increase rate may be adjusted such that the highest temperature during the temperature raising does not exceed the intended temperature, and it is, for example, 1° C./min or higher and 50° C./min or lower.

The temperature of the heat treatment in the modification step of the fifth heat treatment step may be 200° C. or higher and 320° C. or lower, preferably 230° C. or higher and 290° C. or lower. The duration of the heat treatment in the modification step may be, for example, 3 seconds or longer, preferably 1 minute or longer, 10 minutes or longer, 30 minutes or longer, 60 minutes or longer, or 90 minutes or longer. The duration of the heat treatment may be, for example, 300 minutes or shorter, preferably 180 minutes or shorter, or 150 minutes or shorter. The duration of the heat treatment in the modification step is defined that it starts at the time when the temperature reaches a temperature set in the above-described range (e.g., at the time when the temperature reaches 250° C. in a case where the set temperature is 250° C.), and ends at the time when an operation for lowering the temperature is carried out.

The atmosphere of the fifth heat treatment step is preferably an inert gas atmosphere, particularly an argon atmosphere or a nitrogen atmosphere. By using an inert gas atmosphere, the generation of an oxide as a by-product as well as the oxidation of the surfaces of the resulting semiconductor nanoparticles may be reduced or prevented more efficiently.

The method of producing the first semiconductor nanoparticles may further include, after the above-described modification step, the cooling step of lowering the temperature of a dispersion containing the resulting semiconductor nanoparticles. The cooling step starts at the time when an operation for lowering the temperature is carried out, and ends at the time when the dispersion is cooled to 50° C. or lower.

The cooling step may include a period in which the temperature lowering rate is 50° C./min or higher. The temperature lowering rate may be 50° C./min or higher particularly at the time when the temperature starts to decrease after the operation for lowering the temperature is carried out.

The atmosphere of the cooling step is preferably an inert gas atmosphere, particularly an argon atmosphere or a nitrogen atmosphere. By using an inert gas atmosphere, the generation of an oxide as a by-product as well as the oxidation of the surfaces of the resulting semiconductor nanoparticles may be reduced or prevented more efficiently.

The method of producing the first semiconductor nanoparticles may also include a separation step of separating the semiconductor nanoparticles from the dispersion, and may further include a purification step as required. The details of separation step and the purification step are as described above.

### Semiconductor Nanoparticles

The semiconductor nanoparticles contain a third semiconductor containing silver (Ag), indium (In), gallium (Ga), and sulfur (S), and a fourth semiconductor containing Ga and S may be disposed on the surface of the third semiconductor. The semiconductor nanoparticles may have an average particle size of 7.5 nm or larger, an internal quantum yield of 50% or higher, and a full width at half maximum of 30 nm or lower in an emission spectrum. The semiconductor nanoparticles exhibit band-edge emission with an emission peak wavelength in a wavelength range of 475 nm or longer and 560 nm or shorter when irradiated with a light emitted from a light source having an emission peak wavelength in a range of, for example, 380 nm or longer and 545 nm or shorter, and the band-edge emission purity may be 70% or higher. The semiconductor nanoparticles may be produced by, for example, the above-described method of producing semiconductor nanoparticles.

In the semiconductor nanoparticles, a deposit that contains the fourth semiconductor containing Ga and S may be disposed on the surface of the third semiconductor, and particles containing the third semiconductor may be covered with the deposit that contains the fourth semiconductor. Further, the semiconductor nanoparticles may have a core-shell structure in which, for example, a particle containing the third semiconductor constitutes a core and the deposit that contains the fourth semiconductor is disposed as a shell on the surface of the core.

The details of the third semiconductor constituting the semiconductor nanoparticles may be the same as or similar to those of, for example, the first semiconductor constituting the first semiconductor nanoparticles.

In the semiconductor nanoparticles, a fourth semiconductor disposed on the surfaces of the semiconductor nanoparticles may contain a semiconductor containing Ga and S. The fourth semiconductor may contain a semiconductor having a larger band-gap energy than that of the third semiconductor. The composition of the fourth semiconductor may have a higher Ga molar content than the composition of the third semiconductor. A ratio of the Ga molar content in the composition of the fourth semiconductor with respect to the Ga molar content in the composition of the third semiconductor may be, for example, higher than 1 and 5 or lower, preferably 1.1 or higher and 3 or lower.

In the composition of the semiconductor containing Ga and S that is contained in the fourth semiconductor, Ga may be partially substituted with at least one Group 13 element selected from the group consisting of boron (B), aluminum (Al), indium (In), and thallium (Tl). Further, S may be partially substituted with at least one Group 16 element selected from the group consisting of oxygen (O), selenium (Se), tellurium (Te), and polonium (Po).

In an embodiment, the semiconductor containing Ga and S may be a semiconductor substantially composed of Ga and S. The term “substantially” used herein indicates that, when a total number of atoms of all elements contained in the semiconductor containing Ga and S is taken as 100%, a ratio of the number of atoms of elements other than Ga and S is, for example, 10% or lower, preferably 5% or lower, more preferably 1% or lower.

Further, in an embodiment, the fourth semiconductor may also contain Ag in its composition, in addition to Ga and S. When the fourth semiconductor contains Ag in its composition, the content ratio of Ag in the composition of the fourth semiconductor may be, for example, higher than 0% by mole but lower than 30% by mole, preferably 1% by mole or higher, 3% by mole or higher, but preferably 25% by mole or lower, or 10% by mole or lower. In the composition of the fourth semiconductor, a ratio (Ag/(Ag+Ga)) of the number of Ag atoms with respect to a total of the number of Ag atoms and the number of Ga atoms may be, for example, 0.02 or higher and 0.25 or lower, preferably 0.04 or higher, or 0.08 or higher, but preferably 0.50 or lower, or 0.20 or lower. Further, a ratio of the number of S atoms with respect to a total of the number of Ag atoms and the number of Ga atoms may be, for example, 0.25 or higher and 0.75 or lower.

The fourth semiconductor may contain an oxygen (O) atom. An oxygen atom-containing semiconductor tends to have a larger band-gap energy than the above-described third semiconductor. The form of an oxygen atom-containing semiconductor in the fourth semiconductor is not clear; however, it may be, for example, Ga—O—S or Ga₂O₃.

The fourth semiconductor may further contain an alkali metal (M^{a}) in addition to Ga and S. The alkali metal contained in the fourth semiconductor may contain at least lithium. When the fourth semiconductor contains an alkali metal, a ratio of the number of alkali metal atoms with respect to a sum of the number of alkali metal atoms and the number of Ga atoms may be, for example, 0.01 or higher and lower than 1, or 0.1 or higher and 0.9 or lower. Further, a ratio of the number of S atoms with respect to a sum of the number of alkali metal atoms and the number of Ga atoms may be, for example, 0.25 or higher and 0.75 or lower.

The fourth semiconductor may be formed by selecting its composition and the like in accordance with the band-gap energy of the above-described third semiconductor. Alternatively, when the composition and the like of the fourth semiconductor are predetermined, the third semiconductor may be designed such that the band-gap energy of the third semiconductor is smaller than that of the fourth semiconductor. Generally, a semiconductor composed of Ag—In—S has a band-gap energy of 1.8 eV or higher and 1.9 eV or lower.

Specifically, the fourth semiconductor may have a band-gap energy of, for example, 2.0 eV or higher and 5.0 eV or lower, particularly 2.5 eV or higher and 5.0 eV or lower. The band-gap energy of the fourth semiconductor may be larger than that of the third semiconductor by, for example, about 0.1 eV or higher and 3.0 eV or lower, particularly about 0.3 eV or higher and 3.0 eV or lower, more particularly about 0.5 eV or higher and 1.0 eV or lower. When the difference between the band-gap energy of the fourth semiconductor and the band-gap energy of the third semiconductor is equal to or greater than the above-described lower limit value, the ratio of emission other than band-edge emission tends to be reduced, and the ratio of band-edge emission tends to be increased, in the emission from the semiconductor nanoparticles.

The fourth semiconductor may have a crystal system conforming to that of the third semiconductor or the second semiconductor, and may have a lattice constant that is the same as or close to that of the third semiconductor or the second semiconductor. The fourth semiconductor which has a crystal system conforming to that of the third semiconductor or the second semiconductor and a lattice constant close to that of the third semiconductor or the second semiconductor (including a case where a multiple of the lattice constant of the fourth semiconductor is similar to the lattice constant of the third semiconductor or the second semiconductor) may preferably cover the periphery of the third semiconductor or the second semiconductor. For example, the third semiconductor generally has a tetragonal crystal system, and examples of a crystal system conforming thereto include a tetragonal system and an orthorhombic crystal system. When Ag—In—S has a tetragonal crystal system, it is preferred that the lattice constants of its constituent elements be 0.5828 nm, 0.5828 nm, and 1.119 nm, respectively; and that the fourth semiconductor covering this Ag—In—S has a tetragonal or orthorhombic crystal system, and its lattice constants or multiple thereof be close to the lattice constants of Ag—In—S. Alternatively, the fourth semiconductor may be amorphous.

Whether the fourth semiconductor is amorphous or not may be confirmed by observing the semiconductor nanoparticles with HAADF-STEM. When the fourth semiconductor is amorphous, specifically, in HAADF-STEM, a central part is observed with a regular pattern, such as a stripe pattern or a dot pattern, and its surrounding part is observed with no regular pattern. According to HAADF-STEM, a substance having a regular structure as in the case of a crystalline substance is observed as an image having a regular pattern, while a substance having no regular structure as in the case of an amorphous substance is not observed as an image having a regular pattern. Therefore, when the fourth semiconductor is amorphous, the fourth semiconductor may be observed as a part that is clearly different from the third semiconductor observed as an image having a regular pattern (the third semiconductor may have a crystal structure of a tetragonal system or the like).

When the fourth semiconductor is formed of Ga—S, because Ga is an element lighter than Ag and In that are contained in the third semiconductor, the fourth semiconductor tends to be observed darker than the third semiconductor in an image obtained with HAADF-STEM.

Whether the fourth semiconductor is amorphous or not may also be confirmed by observing the semiconductor nanoparticles of the present embodiment under a high-resolution transmission electron microscope (HRTEM). In an image obtained by HRTEM, the third semiconductor portion is observed as a crystal lattice image (an image having a regular pattern) while the fourth semiconductor portion that is amorphous is not observed as a crystal lattice image, and the fourth semiconductor portion is observed as a part having a black and white contrast but no regular pattern.

Meanwhile, the fourth semiconductor preferably does not form a solid solution with the third semiconductor. If the fourth semiconductor forms a solid solution with the third semiconductor, because the fourth semiconductor and the third semiconductor are integrated together, the mechanism of the present embodiment in which the fourth semiconductor is disposed on the surfaces of the semiconductor nanoparticles and the band-edge emission is thereby obtained cannot be attained.

The semiconductor nanoparticles may have an average particle size of, for example, 50 nm or smaller. From the viewpoints of the ease of production and the internal quantum yield of band-edge emission, the average particle size may be in a range of 7 nm or larger and 20 nm or smaller, preferably 7.5 nm or larger, 8 nm or larger, or 8.2 nm or larger, and preferably 15 nm or smaller, 12 nm or smaller, or 11.6 nm or smaller.

The average particle size of the semiconductor nanoparticles may be determined from, for example, a TEM image captured using a transmission electron microscope (TEM). The particle size of individual particle specifically refers to the length of the longest line segment among those line segments that exist inside the particle observed in a TEM image and connect two arbitrary points on the perimeter of the particle. The average particle size of semiconductor nanoparticles is calculated as the arithmetic mean of the particle sizes of the individual particles.

However, for a rod-shaped particle, the length of its short axis is regarded as the particle size. The term “rod-shaped particle” used herein refers to a particle observed in a TEM image to have a short axis and a long axis perpendicular to the short axis, in which a ratio of the length of the long axis with respect to the length of the short axis is higher than 1.2. In a TEM image, a rod-shaped particle is observed to have, for example, a quadrangular shape such as a rectangular shape, an elliptical shape, or a polygonal shape. The shape of a cross-section that is a plane perpendicular to the long axis of the rod shape may be, for example, circular, elliptical, or polygonal. Specifically, for a rod-shaped particle having an elliptical shape, the length of the long axis means the length of the longest line segment among those line segments connecting any two points on the perimeter of the particle and, for a rod-shaped particle having a rectangular or polygonal shape, the length of the long axis means the length of the longest line segment among those line segments that are parallel to the longest side among all sides defining the perimeter of the particle and connect any two points on the perimeter of the particle. The length of the short axis means the length of the longest line segment that is perpendicular to the line segment defining the length of the long axis, among those line segments connecting any two points on the perimeter of the particle.

In the semiconductor nanoparticles, the parts composed of the third semiconductor may be in a particulate form and have an average particle size of, for example, 10 nm or smaller, particularly 8 nm or smaller, or smaller than 7.5 nm. The average particle size of the parts composed of the third semiconductor may be in a range of 1.5 nm or larger and 10 nm or smaller, preferably in a range of 1.5 nm or larger and smaller than 8 nm, or 1.5 nm or larger and smaller than 7.5 nm. When the average particle size of the third semiconductor is equal to or smaller than the above-described upper limit value, a quantum size effect is likely to be obtained. The average particle size of the parts composed of the third semiconductor may be 3 nm or larger, 5 nm or larger, 6 nm or larger, or 7 nm or larger.

In the semiconductor nanoparticles, the parts composed of the fourth semiconductor may have a thickness in a range of 0.1 nm or larger and 20 nm or smaller, particularly in a range of 0.3 nm or larger and 5 nm or smaller. When the thickness of the fourth semiconductor is equal to or larger than the above-described lower limit value, the effect provided by disposing the fourth semiconductor on the semiconductor nanoparticles is sufficiently exerted, so that band-edge emission is likely to be obtained. The thickness of the parts composed of the fourth semiconductor may be 0.1 nm or larger, 0.2 nm or larger, 0.3 nm or larger, 0.5 nm or larger, or 1 nm or larger, and may be 20 nm or smaller, 10 nm or smaller, 5 nm or smaller, 3 nm or smaller, 2 nm or smaller, or 1.5 nm or smaller.

The semiconductor nanoparticles, when irradiated with light having a wavelength range of 380 nm or longer and 545 nm or shorter, may exhibit band-edge emission having an emission peak wavelength in a wavelength range of 475 nm or longer and 560 nm or shorter, and the range of the emission peak wavelength may be preferably 510 nm or longer and 550 nm or shorter, more preferably 525 nm or longer and 535 nm or shorter. Further, in the emission spectrum of the semiconductor nanoparticles, the full width at half maximum may be, for example, 45 nm or lower, preferably 40 nm or lower, 30 nm or lower, 28 nm or lower, or 26.5 nm or lower. The lower limit of the full width at half maximum may be, for example, 15 nm or higher, or 20 nm or higher. Moreover, the emission lifetime of a main component (band-edge emission) is preferably 200 ns or shorter. The full width at half maximum in the emission spectrum of the semiconductor nanoparticles may have a substantially inversely proportional relationship with the particle size of the semiconductor nanoparticles. That is, the semiconductor nanoparticles may have a relationship in which the full width at half maximum becomes narrower as the particle size of the semiconductor nanoparticles increases.

The term “emission lifetime” used herein refers to a lifetime of emission that is measured using a device called fluorescence lifetime measuring device. Specifically, the above-descried “emission lifetime of the main component” may be determined by the following procedure. First, the semiconductor nanoparticles are allowed to emit light by irradiation with an excitation light, and a change in the attenuation (afterglow) over time is measured for a light having a wavelength near the spectral emission peak, for example, a wavelength within a range of the peak wavelength ±50 nm. The measurement of the change over time is initiated upon termination of the irradiation of the excitation light. The resulting attenuation curve is generally a sum of plural attenuation curves derived from relaxation processes of light emission, heat, and the like. Accordingly, in the present embodiment, assuming that the attenuation curve contains three components (i.e. three attenuation curves), parameter fitting is performed such that the attenuation curve is represented by the following formula where I(t) denotes the emission intensity. The parameter fitting is performed using a special software.

$$I ( t ) = {A}_{1} exp ( - t / {τ}_{1} ) + {A}_{2} exp ( - t / {τ}_{2} ) + {A}_{3} exp ( - t / {τ}_{3} )$$

In the above formula, 11, 12, and 13 of the respective components each denote the time required for attenuation of the initial emission intensity to 1/e (36.8%), which corresponds to the emission lifetime of each component. The emission lifetime is in ascending order of τ₁, τ₂, and τ₃. Further, A₁, A₂, and A₃ denote contribution ratios of the respective components. For example, when a component having the largest integral value of curves represented by Aₓexp(−t/τₓ) is defined as the main component, the main component has an emission lifetime t of 200 ns or shorter. Such emission is presumed to be band-edge emission. For identification of the main component, the values of Aₓ×τₓ obtained by integration of the t value of Aₓexp(−t/τₓ) from 0 to infinity are compared, and a component having the largest value is defined as the main component.

An actual attenuation curve is not much different from those attenuation curves that are each drawn from a formula obtained by performing parameter fitting where the emission attenuation curve is assumed to contain three, four, or five components. Therefore, for determination of the emission lifetime of the main component in the present embodiment, the number of components contained in the emission attenuation curve is assumed to be three so as to avoid complicated parameter fitting.

The emission of the semiconductor nanoparticles may include defect emission (e.g., donor-acceptor emission) in addition to band-edge emission; however, the emission is preferably substantially band-edge emission alone. Defect emission generally has a longer emission lifetime and a broader spectrum with a peak on the longer wavelength side as compared to band-edge emission. The expression “substantially band-edge emission alone” used herein means that the purity of the band-edge emission component in the emission spectrum (hereinafter, also referred to as “band-edge emission purity”) is 40% or higher, and this purity is preferably 70% or higher, more preferably 80% or higher, still more preferably 90% or higher, particularly preferably 95% or higher. An upper limit value of the purity of the band-edge emission component may be, for example, 100% or lower, lower than 100%, or 99% or lower. The “purity of the band-edge emission component” is represented by the following formula when parameter fitting, where a band-edge emission peak and a defect emission peak are assumed to each have a shape of normal distribution, is performed for the emission spectrum to separate its peaks into two types, which are the band-edge emission peak and the defect emission peak, and the areas of these peaks are denoted as a₁ and a₂, respectively:

$$Purity ( \% ) of band ‐ edge emission component = {a}_{1} / ( {a}_{1} + {a}_{2} ) \times 100$$

When the emission spectrum contains no band-edge emission at all, i.e. when the emission spectrum contains only defect emission, the purity of the band-edge emission component is 0%; when the emission spectrum contains band-edge emission and defect emission that have the equal peak area, the purity of the band-edge emission component is 50%; and when the emission spectrum contains only band-edge emission, the purity of the band-edge emission component is 100%.

The internal quantum yield of the band-edge emission is defined as a value obtained by multiplying the internal quantum yield, which is measured using a quantum yield measuring device at a temperature of 25° C. and calculated under the any of three following conditions by the above-described purity of the band-edge emission component, and dividing the product by 100. The three conditions are (i) an excitation light wavelength of 450 nm and a fluorescence wavelength range of 470 nm or longer and 900 nm or shorter, (ii) an excitation light wavelength of 365 nm and a fluorescence wavelength range of 450 nm or longer and 950 nm or shorter, or (iii) an excitation light wavelength of 450 nm and a fluorescence wavelength range of 500 nm or longer and 950 nm or shorter. The internal quantum yield of the band-edge emission of the semiconductor nanoparticles is, for example, 15% or higher, preferably 50% or higher, more preferably 60% or higher, still more preferably 70% or higher, particularly preferably 80% or higher.

The peak position of the band-edge emission by the semiconductor nanoparticles may be shifted by modifying the particle size of the semiconductor nanoparticles. For example, when the particle size of the semiconductor nanoparticles is reduced, the peak wavelength of the band-edge emission tends to shift to the shorter wavelength side. A further reduction in the particle size of the semiconductor nanoparticles tends to further reduce the spectral full width at half maximum of the band-edge emission.

When the semiconductor nanoparticles exhibit defect emission in addition to band-edge emission, the intensity ratio of the band-edge emission may be, for example, 0.75 or higher, and it is preferably 0.85 or higher, more preferably 0.9 or higher, particularly preferably 0.93 or higher. An upper limit value thereof may be, for example, 1 or lower, lower than 1, or 0.99 or lower. The intensity ratio of the band-edge emission is represented by the following formula when parameter fitting, where a band-edge emission peak and a defect emission peak are assumed to each have a shape of normal distribution, is performed for the emission spectrum to separate its peaks into two types, which are the band-edge emission peak and the defect emission peak, and the maximum intensities of these peaks are denoted as b₁ and b₂, respectively:

$$Intensity ratio of band ‐ edge emission = {b}_{1} / ( {b}_{1} + {b}_{2} )$$

When the emission spectrum contains no band-edge emission at all, i.e. when the emission spectrum contains only defect emission, the intensity ratio of the band-edge emission is 0; when the emission spectrum contains band-edge emission and defect emission that have the equal maximum peak intensity, the intensity ratio of the band-edge emission is 0.5; and when the emission spectrum contains only band-edge emission, the intensity ratio of the band-edge emission is 1.

The semiconductor nanoparticles preferably exhibit an absorption or excitation spectrum (also referred to as “fluorescence excitation spectrum”) with an exciton peak. An exciton peak is a peak resulting from exciton formation, and the appearance of this peak in an absorption or excitation spectrum means that the particles have a small particle size distribution and few crystal defects, and are thus suitable for band-edge emission. A sharper exciton peak means that an aggregate of the semiconductor nanoparticles contains a greater amount of particles having a uniform particle size with few crystal defects. Accordingly, it is expected that the semiconductor nanoparticles exhibit emission with a narrower full width at half maximum and an improved emission efficiency. In the absorption or excitation spectrum of the semiconductor nanoparticles of the present embodiment, an exciton peak is observed, for example, in a range of 400 nm or longer and 550 nm or shorter, preferably 430 nm or longer and 500 nm or shorter. The excitation spectrum for checking the presence or absence of an exciton peak may be measured by setting the observation wavelength around the peak wavelength.

The surfaces of the semiconductor nanoparticles may be modified with a surface modifier. Specific examples of the surface modifier include an amino alcohol having 2 to 20 carbon atoms, an ionic surface modifier, a nonionic surface modifier, a nitrogen-containing compound containing a hydrocarbon group having 4 to 20 carbon atoms, a sulfur-containing compound containing a hydrocarbon group having 4 to 20 carbon atoms, an oxygen-containing compound containing a hydrocarbon group having 4 to 20 carbon atoms, a phosphorus-containing compound containing a hydrocarbon group having 4 to 20 carbon atoms, and a halide of a Group 2, 12, or 13 element. These surface modifiers may be used singly, or in combination of two or more different kinds thereof. The details of the above-exemplified surface modifiers are as described above.

The surfaces of the semiconductor nanoparticles may be modified with a gallium halide. By modifying the surfaces of the semiconductor nanoparticles with a gallium halide, the internal quantum yield of the band-edge emission is improved. Specific examples of the gallium halide include gallium chloride, gallium fluoride, gallium bromide, and gallium iodide.

The surface of the fourth semiconductor on the semiconductor nanoparticles may be modified with a gallium halide. By modifying the surface of the fourth semiconductor on the semiconductor nanoparticles with a gallium halide, the internal quantum yield of the band-edge emission is improved.

The emission of the semiconductor nanoparticles surface-modified with a gallium halide may include defect emission (donor-acceptor emission) in addition to band-edge emission; however, the emission is preferably substantially band-edge emission alone. The expression “substantially band-edge emission alone” used herein means that, as described for the above-described semiconductor nanoparticles, the purity of the band-edge emission component is preferably 70% or higher, more preferably 80% or higher, still more preferably 90% or higher, particularly preferably 95% or higher.

The measurement of the internal quantum yield of the band-edge emission of the semiconductor nanoparticles surface-modified with a gallium halide is as described for the above-described semiconductor nanoparticles, and the internal quantum yield of the band-edge emission is, for example, 15% or higher, preferably 50% or higher, more preferably 60% or higher, still more preferably 70% or higher, particularly preferably 80% or higher.

### Light Emitting Device

The light emitting device includes: a light conversion member containing the above-described semiconductor nanoparticles; and a semiconductor light emitting element. According to this light emitting device, for example, the semiconductor nanoparticles absorb a portion of the light emitted from the semiconductor light emitting element and emit a longer-wavelength light. Further, the light emitted from the semiconductor nanoparticles is combined with the remainder of the light emitted from the semiconductor light emitting element, and the resulting mixed light may be utilized as a light emitted from the light emitting device.

Specifically, by using a semiconductor light emitting element that emits blue-violet light or blue light having a peak wavelength of about 400 nm to 490 nm as the above-described semiconductor light emitting element and semiconductor nanoparticles that absorb blue light and emit yellow light as the above-described semiconductor nanoparticles, a light emitting device that emits white light may be obtained. A white light emitting device may also be obtained by using, as the above-described semiconductor nanoparticles, two kinds of semiconductor nanoparticles that absorb blue light and emit green light and semiconductor nanoparticles that absorb blue light and emit red light.

Alternatively, a white light emitting device may be obtained even in the case of using a semiconductor light emitting element that emits ultraviolet rays having a peak wavelength of 400 nm or shorter and three kinds of semiconductor nanoparticles that absorb ultraviolet rays and respectively emit blue light, green light, or red light. In this case, it is desired that all of the light emitted from the light emitting element be absorbed and converted by the semiconductor nanoparticles so that the ultraviolet rays emitted from the light emitting element do not leak to the outside.

Further, a white light emitting device may be obtained by using a semiconductor light emitting element that emits blue-green light having a peak wavelength of about 490 nm to 510 nm and semiconductor nanoparticles that absorb the blue-green light and emit red light.

Moreover, it is possible to obtain a light emitting device that emits near-infrared rays by using a semiconductor light emitting element that emits visible light, for example, one which emits red light having a wavelength of 700 nm to 780 nm, as the above-described semiconductor light emitting element, and semiconductor nanoparticles that absorb visible light and emit near-infrared rays as the above-described semiconductor nanoparticles.

The semiconductor nanoparticles may be used in combination with other semiconductor quantum dots, or other phosphors that are not quantum dots (e.g., organic phosphors or inorganic phosphors). The other semiconductor quantum dots are, for example, binary semiconductor quantum dots. As the phosphors that are not quantum dots, for example, garnet-based phosphors such as aluminum-garnet phosphors may be used. Examples of the garnet-based phosphors include a cerium-activated yttrium-aluminum-garnet phosphor, and a cerium-activated lutetium-aluminum-garnet phosphor. Examples of phosphors that may be used also include: nitrogen-containing calcium aluminosilicate-based phosphors activated by europium and/or chromium; silicate-based phosphors activated by europium; nitride-based phosphors, such as β-SiAlON-based phosphors CASN-based or SCASN-based phosphors; rare earth nitride-based phosphors, such as LnSi₃N₁₁-based or LnSiAlON-based phosphors; oxynitride-based phosphors, such as BaSi₂O₂N₂:Eu-based or Ba₃Si₆O₁₂N₂:Eu-based phosphors; sulfide-based phosphors, such as CaS-based, SrGa₂S₄-based, or ZnS-based phosphors; chlorosilicate-based phosphors; SrLiAl₃N₄:Eu phosphor; SrMg₃SiN₄:Eu phosphor; and manganese-activated fluoride complex phosphors, such as a K₂SiF₆:Mn phosphor and a K₂(Si,Al)F₆:Mn phosphor (e.g., K₂Si_{0.99}Al_{0.01}F_{5.99}:Mn).

In the light emitting device, the light conversion member containing the semiconductor nanoparticles may be, for example, a sheet or a plate-like member, or may be a member having a three-dimensional shape. One example of the member having a three-dimensional shape is, in a surface-mount light-emitting diode in which a semiconductor light emitting element is disposed on the bottom surface of a recess formed in a package, an encapsulant that is formed by being supplied in the recess with a resin to encapsulate the light emitting element.

Another example of the light conversion member is, in a case where a semiconductor light emitting element is disposed on a planar substrate, a resin member that is formed in such a manner to surround the upper surface and lateral surfaces of the semiconductor light emitting element with a substantially uniform thickness. Yet another example of the light conversion member is, in a case where a reflective material-containing resin member is supplied to the surrounding of a semiconductor light emitting element such that the upper end of this resin member is flush with the semiconductor light emitting element, a resin member that is formed in a plate-like shape with a predetermined thickness on top of the semiconductor light emitting element and the reflective material-containing resin member.

The light conversion member may be in contact with the semiconductor light emitting element, or may be disposed apart from the semiconductor light emitting element. Specifically, the light conversion member may be a pellet-like, sheet-like, plate-like, or rod-like member disposed apart from the semiconductor light emitting element, or a member disposed in contact with the semiconductor light emitting element, such as an encapsulating member, a coating member (a member covering the light emitting element that is disposed separately from a molded member), or a molded member (e.g., a lens-shaped member).

In the light emitting device, when two or more kinds of semiconductor nanoparticles that emit different wavelengths of light are used, the two or more kinds of semiconductor nanoparticles may be mixed within a single light conversion member, or two or more light conversion members each containing only a single kind of semiconductor nanoparticles may be used in combination. In the latter case, the two or more light conversion members may form a layered structure, or may be disposed in a dot-like or striped pattern on a plane.

An example of the semiconductor light emitting element is an LED chip. The LED chip may include a semiconductor layer composed of one or more selected from the group consisting of GaN, GaAs, InGaN, AlInGaP, GaP, SiC, and ZnO. A semiconductor light emitting element that emits blue-violet light, blue light, or ultraviolet rays includes a semiconductor layer composed of, for example, a GaN compound having a composition represented by In_{X}Al_{Y}Ga_{1-X-Y}N (0≤X, 0≤Y, X+Y<1).

The light emitting device of the present embodiment is preferably incorporated as a light source in a liquid-crystal display device. Because the band-edge emission by the semiconductor nanoparticles has a short emission lifetime, a light emitting device using the semiconductor nanoparticles is suitable as a light source of a liquid-crystal display device that requires a relatively high response speed. Further, the semiconductor nanoparticles of the present embodiment may exhibit band-edge emission having an emission peak with a small full width at half maximum. Therefore, a liquid-crystal display device having good color reproducibility may be obtained without the use of a thick color filter by configuring the light emitting device such that: blue light having a peak wavelength in a range of 420 nm to 490 nm is provided by a blue semiconductor light emitting element, while green light having a peak wavelength in a range of 510 nm to 550 nm, preferably 525 nm to 535 nm, and red light having a peak wavelength in a range of 600 nm to 680 nm, preferably 625 nm to 635 nm, are provided by the semiconductor nanoparticles; or ultraviolet light having a peak wavelength of 400 nm or shorter is provided by a semiconductor light emitting element, while blue light having a peak wavelength in a range of 430 nm to 470 nm, preferably 440 nm to 460 nm, green light having a peak wavelength in a range of 510 nm to 550 nm, preferably 525 nm to 535 nm, and red light having a peak wavelength in a range of 600 nm to 680 nm, preferably 625 nm to 635 nm, are provided by the semiconductor nanoparticles. The light emitting device may be used as, for example, a direct backlight or an edge backlight.

Alternatively, a sheet, a plate-like member, or a rod, which contains the semiconductor nanoparticles and is formed of a resin or glass, may be incorporated into a liquid-crystal display device as a light conversion member independent of the light emitting device.

### EXAMPLES

The present disclosure will now be described more concretely by way of Examples; however, the present disclosure is not limited to the below-described Examples.

### Example 1

### Fourth Step

A fourth mixture was obtained by mixing 1.6 mmol of silver ethyl xanthate (Ag(EX)), 1.76 mmol of indium acetate (In(OAc)₃), 3.2 mmol of gallium ethyl xanthate (Ga(EX)₃), and 0.24 mmol of gallium chloride with 320 mL of oleylamine (OLA). This fourth mixture was heat-treated at 290° C. for 120 minutes with stirring in a nitrogen atmosphere. The thus obtained suspension was allowed to cool and then centrifuged (radius: 146 mm, at 3,800 rpm for 5 minutes), and the resulting precipitate was removed to obtain a dispersion of first semiconductor nanoparticles.

### Fifth Step

A fifth mixture was obtained by mixing the dispersion of the first semiconductor nanoparticles, which was obtained in the above-described fourth step, with 4.74 mmol of gallium chloride and 47 mL of oleylamine (OLA). This fifth mixture was heated to 270° C. in a nitrogen atmosphere to perform a heat treatment for 120 minutes. The thus obtained suspension was allowed to cool and then centrifuged, and the resulting supernatant was removed to obtain a fifth heat-treated product.

### Scanning Transmission Electron Microscope (STEM) Observation

After the fifth step, the shapes of the first semiconductor nanoparticles contained in the fifth heat-treated product were observed under a scanning transmission electron microscope (STEM, manufactured by Hitachi High-Tech Science Corporation, HD-2000), and the average particle size of the first semiconductor nanoparticles was determined from a TEM image captured at a magnification of ×300,000 to ×1,000,000. As a TEM grid, a commercially available copper grid provided with an elastic carbon support film (manufactured by Okenshoji, Co., Ltd.) was used. The above-obtained nanoparticles had a spherical shape or a polygonal shape. The average particle size was determined by a method in which, for all of measurable nanoparticles among those nanoparticles contained in the TEM image, i.e. all particles except for those having their images cut off at the edge of the TEM image, the length of the longest line segment among those line segments existing inside each particle and connecting two arbitrary points on the circumference of the particle was measured as the particle size, and an arithmetic mean of the thus measured values was calculated. When a single TEM image contained less than 100 nanoparticles, another TEM image was captured, and the particle size was measured for the particles contained in this TEM image to determine an arithmetic mean from 100 or more particles. The average particle size of the first semiconductor nanoparticles was 7.3 nm.

### Second Step

Oleylamine was added to and dispersed in the fifth heat-treated product obtained in the fifth step such that the concentration of the first semiconductor nanoparticles was 4.8×10⁻⁷ mol/L. A first mixture was obtained by mixing 22 mL of the resulting dispersion with 0.048 mmol of silver ethyl xanthate (Ag(EX)) and 0.291 mmol of gallium ethyl xanthate (Ga(EX)₃). This first mixture was subjected to a 120-minute first heat treatment at 270° C. with stirring in a nitrogen atmosphere. The thus obtained suspension was allowed to cool, whereby a first heat-treated product containing semiconductor composite particles was obtained.

### Third Step

A second mixture was obtained by mixing the first heat-treated product containing semiconductor composite particles, which was obtained in the second step, with 0.291 mmol of gallium chloride and 2.9 mL of oleylamine (OLA). This second mixture was heated to 270° C. in a nitrogen atmosphere to perform a second heat treatment for 120 minutes. The thus obtained suspension was allowed to cool, whereby a second heat-treated product containing second semiconductor nanoparticles was obtained.

### Measurement of Emission Spectrum of Second Heat-Treated Product

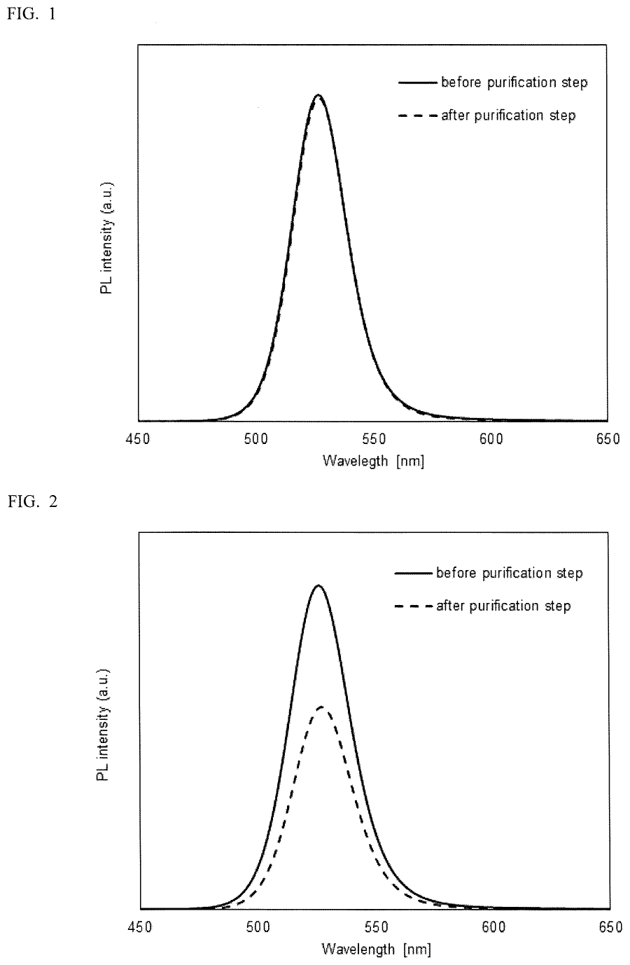

Before the purification step, an emission spectrum of the above-obtained second heat-treated product containing the second semiconductor nanoparticles was measured, and the band-edge emission peak wavelength, the full width at half maximum, the band-edge emission purity, and the internal quantum yield of band-edge emission were determined. The emission spectrum was measured in a wavelength range of 300 nm to 950 nm using a quantum efficiency measurement system (trade name: QE-2100, manufactured by Otsuka Electronics Co., Ltd.) at room temperature (25° C.) with an excitation light wavelength of 365 nm. The internal quantum yield was calculated for a wavelength range of 450 nm to 950 nm. The results thereof are shown in Table 1 and FIG. 1.

### Purification Step

The second heat-treated product containing the second semiconductor nanoparticles obtained in the third step was centrifuged, and the resulting supernatant was removed to obtain a precipitate, and then the obtained precipitate was washed with 15 mL of ethanol. After this washing, the resultant was centrifuged, and a precipitate obtained by removal of the resulting supernatant was dispersed in 5 mL of chloroform. Thereafter, the semiconductor nanoparticles were washed with an addition of 22 mL of ethanol thereto, and the resultant was again centrifuged to recover the second semiconductor nanoparticles as a precipitate, which was then dispersed in 5 mL of chloroform to obtain post-purification-step second semiconductor nanoparticles.

### Measurement of Emission Spectrum of Second Semiconductor Nanoparticles

An emission spectrum of the above-obtained post-purification-step second semiconductor nanoparticles was measured, and the band-edge emission peak wavelength, the full width at half maximum, the band-edge emission purity, and the internal quantum yield of band-edge emission were determined. Subsequently, the second semiconductor nanoparticles were observed under a scanning transmission electron microscope in the same manner as or similar manner to described above to calculate the average particle size. The results thereof are shown in Table 1. In addition, the emission spectra of the semiconductor nanoparticles before and after the purification step are shown in FIG. 1.

### COMPARATIVE EXAMPLE

The fifth heat-treated product obtained in the fifth step of Example 1 was dispersed in chloroform to obtain pre-purification-step semiconductor nanoparticles of Comparative Example. Further, the fifth heat-treated product obtained in the fifth step was washed with 15 mL of ethanol. After this washing, the resultant was centrifuged, and a precipitate obtained by removal of the resulting supernatant was dispersed in 5 mL of chloroform. Thereafter, the semiconductor nanoparticles were washed with an addition of 22 mL of ethanol thereto, and the resulting precipitate was removed through centrifugation again to obtain a precipitate, which was then dispersed in 5 mL of chloroform to obtain post-purification-step semiconductor nanoparticles of Comparative Example. For the semiconductor nanoparticles of Comparative Example, the results of measuring emission spectrum in the same manner as in or similar manner to Example 1 are shown in Table 1. In addition, the emission spectra of the semiconductor nanoparticles before and after the purification step are shown in FIG. 2.

### Example 2

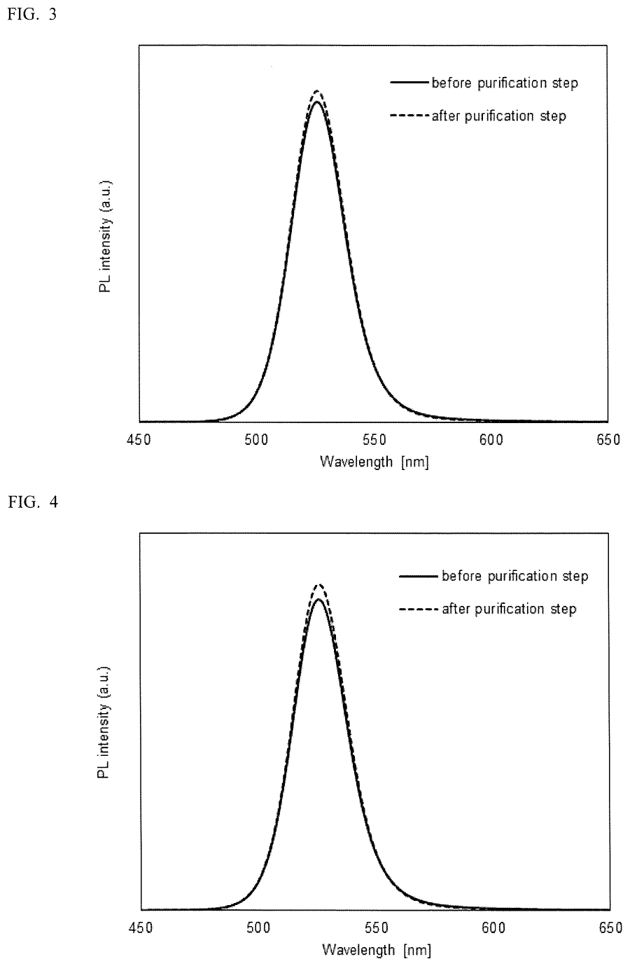

A dispersion of second semiconductor nanoparticles was obtained in the same manner as in or similar manner to Example 1, except that the amount of gallium ethyl xanthate (Ga(EX)₃) mixed in the second step was changed to 0.466 mmol to obtain the first mixture. For the thus obtained second heat-treated product and second semiconductor nanoparticles, the results of measuring emission spectrum in the same manner as in or similar manner to Example 1 and the result of calculating the average particle size are shown in Table 1. In addition, the emission spectra of the semiconductor nanoparticles before and after the purification step are shown in FIG. 3.

### Example 3

A dispersion of second semiconductor nanoparticles was obtained in the same manner as in or similar manner to Example 1, except that the amount of gallium ethyl xanthate (Ga(EX)₃) mixed in the second step was changed to 0.582 mmol to obtain the first mixture. For the thus obtained second heat-treated product and second semiconductor nanoparticles, the results of measuring emission spectrum in the same manner as in or similar manner to Example 1 and the result of calculating the average particle size are shown in Table 1. In addition, the emission spectra of the semiconductor nanoparticles before and after the purification step are shown in FIG. 4.

### Example 4

A dispersion of second semiconductor nanoparticles was obtained in the same manner as in or similar manner to Example 1, except that, in the second step, 0.291 mmol of gallium ethyl xanthate (Ga(EX)₃) was mixed without mixing silver ethyl xanthate (Ag(EX)) to obtain the first mixture. For the thus obtained second heat-treated product and second semiconductor nanoparticles, the results of measuring emission spectrum in the same manner as in or similar manner to Example 1 and the result of calculating the average particle size are shown in Table 1. In addition, the emission spectra of the semiconductor nanoparticles before and after the purification step are shown in FIG. 5.

TABLE 1

| | | | | Emission characteristics | | | |
|---|---|---|---|---|---|---|---|
| | | | Average | (before purification step) | | | |
| | | | particle | | Full | | |
| | | | size after | Peak | width | Internal | Band-edge |
| | First mixture | | purification | emission | at half | quantum | emission |
| | Ag(EX) | Ga(EX)₃ | step | wavelength | maximum | yield | purity |
| | [mmol] | [mmol] | [nm] | [nm] | [nm] | [%] | [%] |
| Example 1 | 0.048 | 0.291 | 10.4 | 527 | 26 | 84 | 95 |
| Comparative | — | — | — | 526 | 29 | 78 | 91 |
| Example | | | | | | | |
| Example 2 | 0.048 | 0.466 | 9.7 | 526 | 26 | 82 | 93 |
| Example 3 | 0.048 | 0.582 | 9.8 | 526 | 26 | 82 | 92 |
| Example 4 | — | 0.291 | 7.7 | 526 | 27 | 78 | 94 |

| | Emission characteristics | | | | |
|---|---|---|---|---|---|
| | (after purification step) | | | | |
| | | Full | | | Differece |
| | Peak | width | Internal | Band-edge | in internal |
| | emission | at half | quantum | emission | quantum |
| | wavelength | maximum | yield | purity | yield |
| | [nm] | [nm] | [%] | [%] | [%] |
| Example 1 | 527 | 26 | 83 | 95 | −1 |
| Comparative | 527 | 29 | 47 | 91 | −31 |
| Example | | | | | |
| Example 2 | 526 | 26 | 85 | 94 | 3 |
| Example 3 | 526 | 26 | 86 | 93 | 4 |
| Example 4 | 526 | 27 | 74 | 92 | −4 |

As shown in Table 1, a reduction in the internal quantum yield after the purification step can be suppressing by performing the second step.

### Examples 5 to 17

Second heat-treated products containing the second semiconductor particles were obtained in the same manner as in or similar manner to Example 1, except that the amounts of silver ethyl xanthate (Ag(EX)) and gallium ethyl xanthate (Ga(EX)₃) mixed in the second step was changed as shown in Table 2 below.

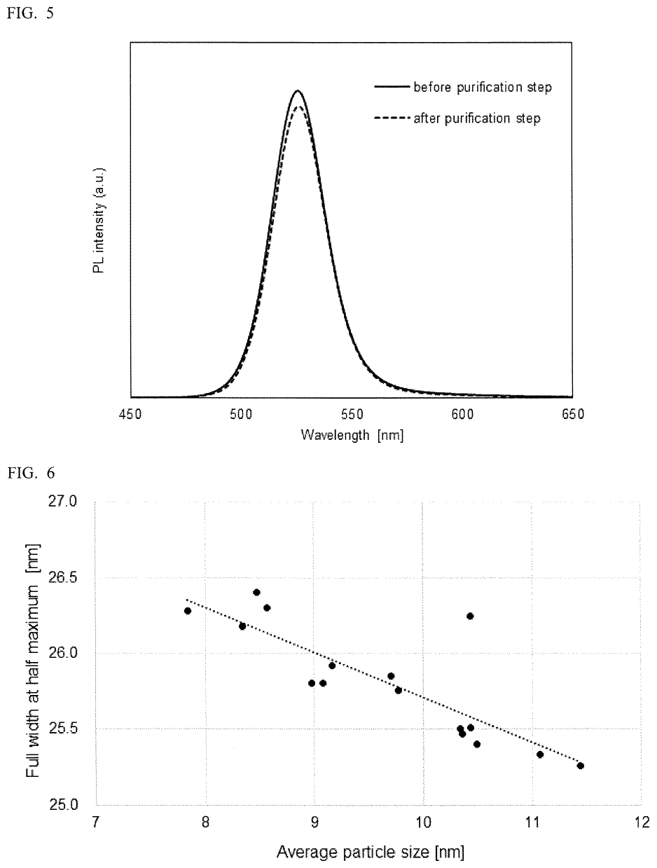

For the obtained second semiconductor nanoparticles before the purification step, the average particle size and the full width at half maximum in the emission spectrum were measured in the same manner as or similar manner to described above. The results are shown in Table 2. The relationship between the average particle size and the full width at half maximum are shown in FIG. 6.

TABLE 2

| | | | | Full width |
|---|---|---|---|---|
| | | | Average | at half |
| | Ag(EX) | Ga(EX)₃ | particle size | maximum |
| | [mmol] | [mmol] | [nm] | [nm] |
| Example 1 | 0.048 | 0.291 | 10.4 | 26.2 |
| Example 2 | 0.048 | 0.466 | 9.7 | 25.8 |
| Example 3 | 0.048 | 0.582 | 9.8 | 25.8 |
| Example 5 | 0.077 | 0.466 | 11.1 | 25.3 |
| Example 6 | 0.048 | 0.291 | 9.2 | 25.9 |
| Example 7 | 0.024 | 0.291 | 8.4 | 26.2 |
| Example 8 | 0.048 | 0.146 | 9.0 | 25.8 |
| Example 9 | 0.024 | 0.146 | 8.6 | 26.3 |
| Example 10 | 0.024 | 0.582 | 7.8 | 26.3 |
| Example 11 | 0.072 | 0.582 | 10.4 | 25.5 |
| Example 12 | 0.096 | 0.582 | 11.4 | 25.3 |
| Example 13 | 0.048 | 0.728 | 8.5 | 26.4 |
| Example 14 | 0.072 | 0.728 | 10.3 | 25.5 |
| Example 15 | 0.048 | 0.873 | 9.1 | 25.8 |
| Example 16 | 0.072 | 0.873 | 10.5 | 25.4 |
| Example 17 | 0.048 | 0.466 | 10.4 | 25.5 |

As shown in Table 2 and FIG. 6, the second semiconductor nanoparticles tend to have a narrower full width at half maximum as the average particle size increases.

It is to be understood that although the present invention has been described with regard to preferred embodiments thereof, various other embodiments and variants may occur to those skilled in the art, which are within the scope and spirit of the invention, and such other embodiments and variants are intended to be covered by the following claims.

Although the present disclosure has been described with reference to several exemplary embodiments, it is to be understood that the words that have been used are words of description and illustration, rather than words of limitation. Changes may be made within the purview of the appended claims, as presently stated and as amended, without departing from the scope and spirit of the disclosure in its aspects. Although the disclosure has been described with reference to particular examples, means, and embodiments, the disclosure may be not intended to be limited to the particulars disclosed; rather the disclosure extends to all functionally equivalent structures, methods, and uses such as are within the scope of the appended claims.

One or more examples or embodiments of the disclosure may be referred to herein, individually and/or collectively, by the term “disclosure” merely for convenience and without intending to voluntarily limit the scope of this application to any particular disclosure or inventive concept. Moreover, although specific examples and embodiments have been illustrated and described herein, it should be appreciated that any subsequent arrangement designed to achieve the same or similar purpose may be substituted for the specific examples or embodiments shown. This disclosure may be intended to cover any and all subsequent adaptations or variations of various examples and embodiments. Combinations of the above examples and embodiments, and other examples and embodiments not specifically described herein, will be apparent to those of skill in the art upon reviewing the description.

In addition, in the foregoing Detailed Description, various features may be grouped together or described in a single embodiment for the purpose of streamlining the disclosure. This disclosure may be not to be interpreted as reflecting an intention that the claimed embodiments require more features than are expressly recited in each claim. Rather, as the following claims reflect, inventive subject matter may be directed to less than all of the features of any of the disclosed embodiments. Thus, the following claims are incorporated into the Detailed Description, with each claim standing on its own as defining separately claimed subject matter.

The above disclosed subject matter shall be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure may be determined by the broadest permissible interpretation of the following claims and their equivalents, and shall not be restricted or limited by the foregoing detailed description.

All publications, patent applications, and technical standards mentioned in this specification are herein incorporated by reference to the same extent as if each individual publication, patent application, or technical standard was specifically and individually indicated to be incorporated by reference.

What is claimed is:

1. A method of producing semiconductor nanoparticles, the method comprising:
providing first semiconductor nanoparticles comprising a first semiconductor comprising silver (Ag), indium (In), gallium (Ga), and sulfur (S), and a second semiconductor disposed on a surface of the first semiconductor and comprising gallium (Ga) and sulfur (S);
performing a first heat treatment of a first mixture comprising the first semiconductor nanoparticles, a gallium (Ga) source, and a sulfur (S) source, to obtain a first heat-treated product comprising semiconductor composite particles; and
performing a second heat treatment of a second mixture comprising the semiconductor composite particles and a gallium halide, to obtain a second heat-treated product.

2. The method of producing semiconductor nanoparticles according to claim 1, wherein the first mixture further comprises a silver (Ag) source.

3. The method of producing semiconductor nanoparticles according to claim 2, wherein
a ratio of a number of moles of silver contained in the silver (Ag) source with respect to a number of moles of the first semiconductor nanoparticles contained in the first mixture is 1.0×10³ to 1.0×10⁴, and
a ratio of a number of moles of gallium contained in the gallium (Ga) source with respect to the number of moles of the first semiconductor nanoparticles is 5.0×10³ to 8.0×10⁴.

4. The method of producing semiconductor nanoparticles according to claim 2, wherein a ratio of a number of moles of silver contained in the silver (Ag) source with respect to a number of moles of gallium contained in the gallium (Ga) source contained in the first mixture is 0.04 to 0.33.

5. The method of producing semiconductor nanoparticles according to claim 1, the method further comprising:
mixing the second heat-treated product with an organic solvent to obtain a third mixture; and
performing centrifugation of the third mixture.

6. The method of producing semiconductor nanoparticles according to claim 5, wherein a ratio of an internal quantum yield of the semiconductor nanoparticles obtained after the centrifugation with respect to an internal quantum yield of the semiconductor nanoparticles contained in the second heat-treated product is 0.7 to 1.1.

7. The method of producing semiconductor nanoparticles according to claim 5, wherein the organic solvent comprises an alcohol solvent.

8. The method of producing semiconductor nanoparticles according to claim 1, wherein
a heat treatment temperature in the first heat treatment is 200° C. to 320° C., and
a heat treatment temperature in the second heat treatment is 200° C. to 320° C.

9. The method of producing semiconductor nanoparticles according to claim 1, wherein a ratio of a number of moles of gallium contained in the gallium (Ga) source with respect to the number of moles of the first semiconductor nanoparticles contained in the first mixture is 5.0×10³ to 6.0×10⁴.

10. Semiconductor nanoparticles, comprising:
a semiconductor comprising silver (Ag), indium (In), gallium (Ga), and sulfur (S); and
an additional semiconductor disposed on a surface of the semiconductor and comprising Ga and S,
wherein the semiconductor nanoparticles have an average particle size that is 7.5 nm or larger, an internal quantum yield that is 50% or higher, and a full width at half maximum that is 30 nm or lower in an emission spectrum.

11. The semiconductor nanoparticles according to claim 10, wherein the additional semiconductor further comprises silver (Ag).

12. The semiconductor nanoparticles according to claim 11, wherein the semiconductor nanoparticles have an average particle size that is 10 nm or larger.

13. The semiconductor nanoparticles according to claim 10, wherein the semiconductor nanoparticles are produced by the method according to claim 1.

14. The semiconductor nanoparticles according to claim 11, wherein the semiconductor nanoparticles are produced by the method according to claim 1.
